(19) United States
(12) Patent Application Publication
(10) Pub. No.: US 2025/0203866 A1
(43) Pub. Date: Jun. 19, 2025

(54) SEMICONDUCTOR MEMORY DEVICE AND METHOD OF A MANUFACTURING THE SEMICONDUCTOR MEMORY DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/679,093

(22) Filed: May 30, 2024

(30) Foreign Application Priority Data
Dec. 19, 2023 (KR) 10-2023-0185993

(51) Int. Cl. H10B 43/27; H01L 23/528; H01L 23/532; H10B 41/27; H10B 41/35; H10B 43/35

(52) U.S. Cl. CPC H10B 43/27; H01L 23/5283; H01L 23/53295; H10B 41/27; H10B 41/35; H10B 43/35

(57) ABSTRACT

Provided herein is a semiconductor memory device and a method of manufacturing the semiconductor memory device. The semiconductor memory device includes a plurality of first conductive layers of a first sub-stacked body, a plurality of second conductive layers of a second sub-stacked body disposed over the first sub-stacked body, and a first gate contact plug contacting a corresponding second conductive layer among the plurality of second conductive layers. The first gate contact plug includes a first contact portion contacting the corresponding second conductive layer, a first portion penetrating the first sub-stacked body, and a second portion extending from the first portion toward the first contact portion.

### CROSS-REFERENCE TO RELATED APPLICATION

The present application claims priority under 35 U.S.C. § 119(a) to Korean patent application number 10-2023-0185993 filed on Dec. 19, 2023, in the Korean Intellectual Property Office, the entire disclosure of which application is incorporated by reference herein.

### BACKGROUND

### 1. Technical Field

Various embodiments of the present disclosure generally relate to a semiconductor memory device and a method of manufacturing the semiconductor memory device, and more particularly, to a 3D semiconductor memory device and a method of manufacturing the 3D semiconductor memory device.

### 2. Related Art

A semiconductor memory device may be applied to a small electronic device as well as electronic systems in various fields such as automobiles, medical fields, or data centers. Thus, there is a growing demand for semiconductor memory devices.

The semiconductor memory device may include a memory cell for storing data. A 3D semiconductor memory device includes memory cells arranged in three dimensions, so that the 3D semiconductor memory device may be advantageous in achieving a large capacity compared to a 2D semiconductor memory device.

The integration degree of memory cells in the 3D semiconductor memory device can be improved by increasing the number of the memory cells stacked. As the number of the stacked memory cells increases, the number of stacked conductive layers coupled to the memory cell may increase. The conductive layer may be electrically connected to a peripheral circuit via a contact plug.

### SUMMARY

An embodiment of the present disclosure may provide for a semiconductor memory device. The semiconductor memory device may include a gate stacked body including a cell array area and a contact area extending from the cell array area in a first direction, and including a plurality of conductive layers and a plurality of interlayer insulating layers that are alternately stacked in a second direction intersecting a plane extending in the first direction, and a plurality of gate contact plugs penetrating the plurality of conductive layers and the plurality of interlayer insulating layers in the contact area, wherein the plurality of conductive layers may include a plurality of first conductive layers arranged in the second direction to form a first sub-stacked body and a plurality of second conductive layers arranged over the first sub-stacked body in the second direction to form a second sub-stacked body, the plurality of gate contact plugs may include a first gate contact plug contacting a corresponding second conductive layer among the plurality of second conductive layers, the first gate contact plug may include a first portion penetrating the first sub-stacked body, a first contact portion spaced apart from the first portion in the second direction and contacting the corresponding second conductive layer, and a second portion extending from the first portion toward the first contact portion, and the second portion in the first direction may be narrower than the first contact portion.

An embodiment of the present disclosure may provide for a semiconductor memory device. The semiconductor memory device may include a gate stacked body including a cell array area and a contact area extending from the cell array area in a first direction, and including a plurality of conductive layers and a plurality of interlayer insulating layers that are alternately stacked in a second direction intersecting a plane extending in the first direction, and a first sub-contact set including a plurality of first gate contact plugs penetrating the plurality of conductive layers and the plurality of interlayer insulating layers in the contact area, wherein the plurality of conductive layers may include a plurality of first conductive layers arranged in the second direction to form a first sub-stacked body and a plurality of second conductive layers arranged over the first sub-stacked body in the second direction to form a second sub-stacked body and contact the plurality of first gate contact plugs, respectively, the first sub-contact set may include a plurality of first portions penetrating the first sub-stacked body and forming lower portions of the plurality of first gate contact plugs, a plurality of first contact portions forming upper portions of the plurality of first gate contact plugs, and a plurality of second portions forming middle portions of the plurality of first gate contact plugs, and a sidewall of each of the plurality of first gate contact plugs may include a groove defined between a corresponding first contact portion among the plurality of first contact portions and a corresponding first portion among the plurality of first portions.

An embodiment of the present disclosure may provide for a method of manufacturing a semiconductor memory device. The method may include forming a first opening that passes through a first stacked body, forming a sacrificial pillar in the first opening, forming a second stacked body over the first stacked body, forming a first type of second opening in the second stacked body to overlap the sacrificial pillar, forming a first preliminary hole by etching a portion of the second stacked body between the sacrificial pillar and the first type of second opening through the first type of second opening, the first preliminary hole exposing the sacrificial pillar and being narrower than the first type of second opening, removing the sacrificial pillar, forming a first sidewall insulating layer along an inner wall of a first contact hole defined by coupling the first opening, the first preliminary hole, and the first type of second opening and including a first guide corresponding to a bottom surface of the first type of second opening, removing a portion of the first sidewall insulating layer so that the first guide of the first contact hole is opened, and forming a first gate contact plug in the first contact hole.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell array and a pass circuit according to an embodiment of the present disclosure.

FIGS. 3A and 3B are diagrams illustrating a semiconductor memory device according to embodiments of the present disclosure.

FIGS. 4A, 4B, 4C, and 4D are sectional views illustrating a cell array area and a contact area of a semiconductor memory device according to an embodiment of the present disclosure.

FIGS. 5A, 5B, 5C, 5D, 5E, 5F, 5G, 5H, 5I, 5J, 5K, 5L, 5M, 5N, 5O, 5P, 5Q, 5R, and 5S are sectional views illustrating a method of manufacturing a semiconductor memory device according to an embodiment of the present disclosure.

FIG. 6 is a block diagram illustrating an electronic system according to an embodiment of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms. The cross-hatching throughout the figures illustrates corresponding or similar areas between the figures rather than indicating the materials for the areas. It will be understood that when an element or layer etc., is referred to as being “on,” “over,” “connected to,” or “coupled to” another element or layer etc., it can be directly on, over, connected, or coupled to the other element or layer etc., or intervening elements or layers etc., may be present. In contrast, when an element or layer etc., is referred to as being “directly on,” “directly over,” “directly connected to” or “directly coupled to” another element or layer etc., there are no intervening elements or layers etc., present. Like numerals refer to like elements throughout. As used herein, the term “and/or” includes any and all combinations of one or more of the associated listed items. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

Various embodiments of the present disclosure are directed to a semiconductor memory device and a method of manufacturing the semiconductor memory device, which can improve operational reliability.

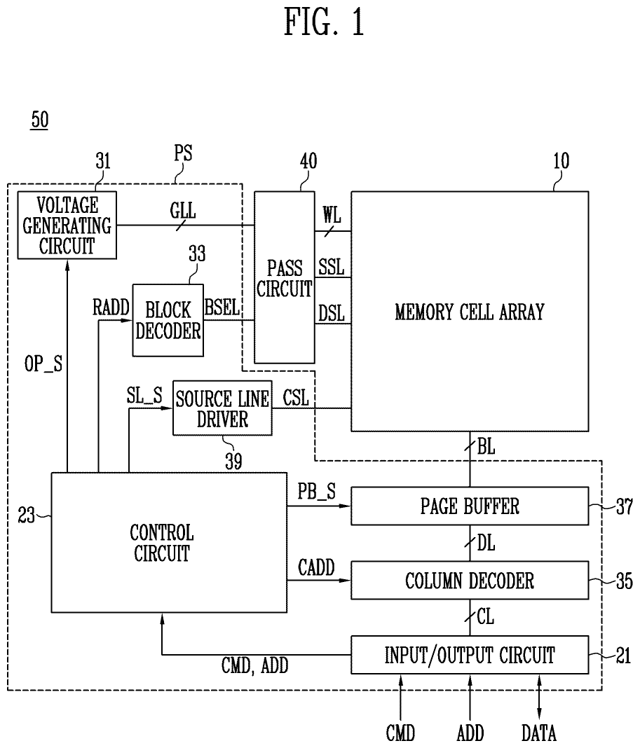

FIG. 1 is a block diagram illustrating a semiconductor memory device according to an embodiment of the present disclosure.

Referring to FIG. 1, a semiconductor memory device 50 may include a memory cell array 10, a pass circuit 40, and a peripheral circuit structure PS.

The memory cell array 10 may include a plurality of memory blocks. Each memory block may include a plurality of memory cells. Each memory cell may be a nonvolatile memory cell. In an embodiment, each memory cell may be a NAND flash memory cell. Hereinafter, embodiments of the present disclosure will be described based on the semiconductor memory device 50 including NAND flash memory cells, but the present disclosure is not limited thereto. In an embodiment, each memory cell may be implemented as a ferroelectric memory cell, a variable-resistance memory cell, or the like.

The pass circuit 40 may be coupled to the memory cell array 10 through a plurality of local lines. In an embodiment, the plurality of local lines may include a plurality of word lines WL, at least one source select line SSL, and at least one drain select line DSL.

The peripheral circuit structure PS may perform a program operation of storing data in the memory cell array 10, a read operation of outputting data stored in the memory cell array 10, and an erase operation of erasing data stored in the memory cell array 10. In an embodiment, the peripheral circuit structure PS may include an input/output circuit 21, a control circuit 23, a voltage generating circuit 31, a block decoder 33, a column decoder 35, a page buffer 37, and a source line driver 39.

The input/output circuit 21 may transfer a command CMD and an address ADD, received from an external device (e.g., a memory controller) of the semiconductor memory device 50, to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate and output various operating voltages that are used for a program operation, a read operation, and an erase operation in response to the operation signal OP_S. The operating voltages output from the voltage generating circuit 31 may be transmitted to the pass circuit 40 through a plurality of global lines GLL.

The block decoder 33 may output a block selection signal in response to the row address RADD. The block selection signal output from the block decoder 33 may be transmitted to the pass circuit 40 through a block select line BSEL.

The pass circuit 40 may transfer the operating voltages transmitted to the plurality of global lines GLL to the drain select line DSL, the word lines WL, and the source select line SSL in response to the block selection signal transmitted to the block select line BSEL.

The column decoder 35 may transmit the data DATA, input from the input/output circuit 21, to the page buffer 37 or transmit data DATA, stored in the page buffer 37, to the input/output circuit 21 in response to the column address CADD. The column decoder 35 may exchange data DATA with the input/output circuit 21 through column lines CL. The column decoder 35 may exchange data DATA with the page buffer 37 through data lines DL.

The page buffer 37 may store the read data, received through bit lines BL, in response to the page buffer control signal PB_S. The page buffer 37 may sense the voltages or currents of the bit lines BL during a read operation. The page buffer 37 may be coupled to the memory cell array 10 through the bit lines BL.

The source line driver 39 may control a voltage applied to a common source line CSL in response to the source line control signal SL_S. The source line driver 39 may be coupled to the memory cell array 10 through the common source line CSL.

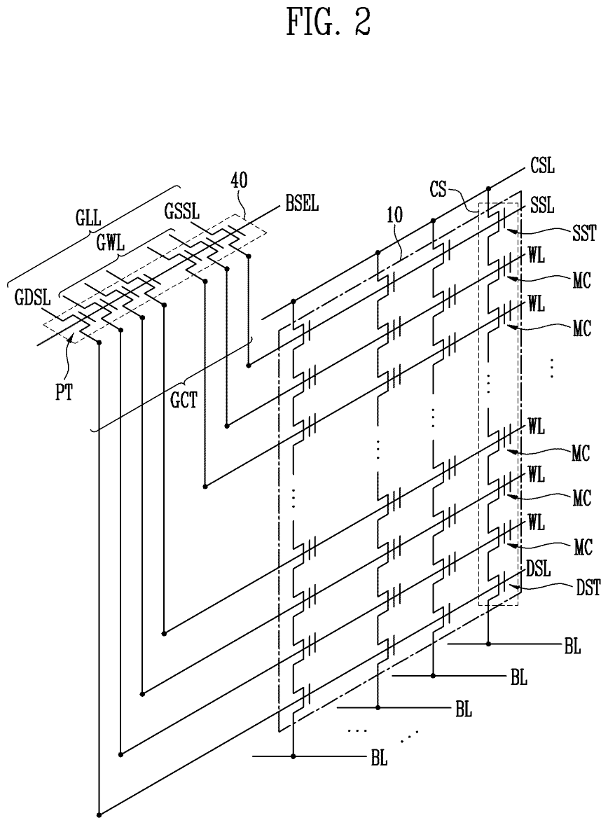

FIG. 2 is a circuit diagram illustrating a memory cell array and a pass circuit according to an embodiment of the present disclosure.

Referring to FIG. 2, the memory cell array 10 may include a plurality of memory cell strings CS. The plurality of memory cell strings CS may be coupled to a plurality of bit lines BL and a common source line CSL.

Each memory cell string CS may include at least one source select transistor SST, a plurality of memory cells MC, and at least one drain select transistor DST.

The source select transistor SST may control an electrical connection between the plurality of memory cells MC and the common source line CSL. The drain select transistor DST may control an electrical connection between the plurality of memory cells MC and the corresponding bit line BL.

One source select transistor SST or two series-connected source select transistors may be disposed between the common source line CSL and the plurality of memory cells MC. One drain select transistor DST or two or more series-connected drain select transistors may be disposed between each bit line BL and a plurality of memory cells MC of a memory cell string CS corresponding to the bit line BL.

A plurality of gates of the plurality of memory cells MC may be coupled to the plurality of word lines WL, respectively. A gate of the source select transistor SST may be coupled to a source select line SSL. A gate of the drain select transistor DST may be coupled to the drain select line DSL.

The source select line SSL, the drain select line DSL, and the plurality of word lines WL may be coupled to the pass circuit 40. The pass circuit 40 may include pass transistor groups, each including a plurality of pass transistors PT coupled to the same pass block select line BSEL. The plurality of pass transistors PT may be coupled to a plurality of gate contact plugs GCT, respectively. The plurality of gate contact plugs GCT may be coupled to the source select line SSL, the drain select line DSL, and the plurality of word lines WL, respectively. Each of the pass transistors PT may be coupled to a corresponding local line among the source select line SSL, the drain select line DSL, and the plurality of word lines WL via the gate contact plug GCT corresponding to the pass transistor PT.

The plurality of pass transistors PT may transfer the voltages, applied to the plurality of global lines GLL, to the source select line SSL, the drain select line DSL, and the plurality of word lines WL in response to the block selection signal applied to the block select line BSEL. The plurality of global lines GLL may include a global source select line GSSL, a global drain select line GDSL, and a plurality of global word lines GWL, which correspond to the source select line SSL, the drain select line DSL, and the plurality of word lines WL, respectively.

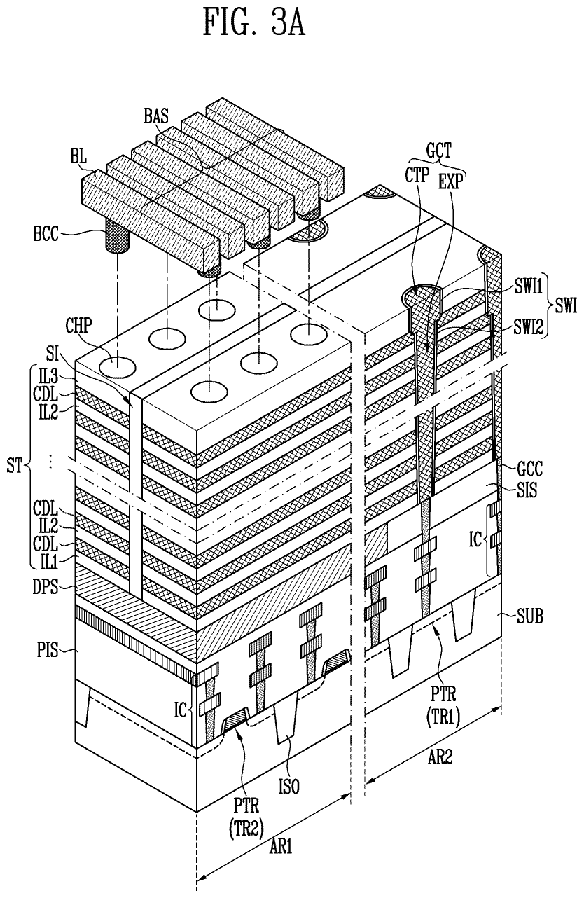

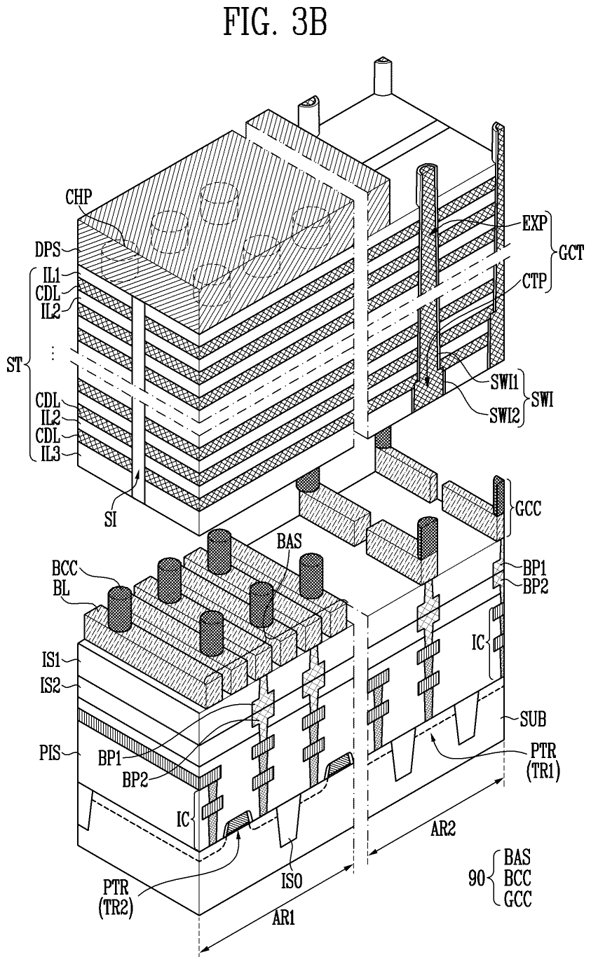

FIGS. 3A and 3B are diagrams illustrating a semiconductor memory device according to embodiments of the present disclosure.

Referring to FIGS. 3A and 3B, the semiconductor memory device may include a bit line array BAS and a doped semiconductor structure DPS. The memory cell array 10 described with reference to FIG. 2 may be disposed between the bit line array BAS and the doped semiconductor structure DPS. The memory cell array 10 described with reference to FIG. 2 may include a plurality of channel pillars CHP and a plurality of gate stacked bodies ST.

The doped semiconductor structure DPS may include at least one doped semiconductor layer. The doped semiconductor structure DPS may include at least one of a first conductivity type doped area including an n-type impurity as a majority carrier and a second conductivity type doped area including a p-type impurity as a majority carrier. The first conductivity type doped area may be provided as a common source area, and the second conductivity type doped area may be provided as a well area. The first conductivity type doped area of the doped semiconductor structure DPS may be coupled to a common source line CSL described with reference to FIG. 2.

The bit line array BAS may include a plurality of bit lines BL.

Each gate stacked body ST may include a plurality of conductive layers CDL and a plurality of interlayer insulating layers IL1, IL2, and IL3 that are alternately stacked between the bit line array BAS and the doped semiconductor structure DPS. Each of the plurality of conductive layers CDL may include various conductive materials such as a doped semiconductor layer and a metal layer. The doped semiconductor layer may include a doped silicon layer. The metal layer may include tungsten, copper, molybdenum, etc. Each conductive layer CDL may further include a conductive metal nitride layer provided as a barrier layer. The conductive metal nitride layer may include titanium nitride, tantalum nitride, etc. Each of the plurality of interlayer insulating layers IL1, IL2, and IL3 may include an insulating material such as a silicon oxide layer. The plurality of interlayer insulating layers IL1, IL2, and IL3 may include a source-side interlayer insulating layer IL1 adjacent to the doped semiconductor structure DPS, a bit line-side interlayer insulating layer IL3 adjacent to the bit line array BAS, and an intervening interlayer insulating layer IL2 disposed between neighboring conductive layers CDL.

A slit SI may be defined between neighboring gate stacked bodies ST. A filler may be disposed in the slit SI and may be designed in various ways. According to an embodiment, the filler may include an insulating layer. According to an embodiment, the filler may further include at least one of a conductive layer and a semiconductor layer, in addition to the insulating layer.

The plurality of conductive layers CL may include at least one source select line SSL adjacent to the doped semiconductor structure DPS, at least one drain select line DSL adjacent to the bit line array BAS and a plurality of word lines WL, as illustrated in FIG. 2.

The gate stacked body ST may include a cell array area AR1 and a contact area AR2 extending from the cell array area AR1. The contact area AR2 of the gate stacked body ST may protrude laterally compared to the doped semiconductor structure DPS.

Each of the plurality of conductive layers CDL and the plurality of interlayer insulating layers IL1, IL2, and IL3 may enclose a sidewall of each of the plurality of channel pillars CHP in the cell array area AR1. Each channel pillar CHP may include a channel layer of the memory cell string CS described with reference to FIG. 2. The channel layer of the channel pillar CHP may be electrically connected to a corresponding bit line BL via a bit line coupling structure BCC. The channel layer of the channel pillar CHP may include a contact surface that is in contact with the doped semiconductor structure DPS. The contact surface may be defined on a portion of a sidewall of the channel pillar CHP, an end of the channel pillar CHP or the like. According to an embodiment, referring to FIG. 3B, the doped semiconductor structure DPS may include a groove into which the end of the channel pillar CHP is inserted, and a contact surface between the doped semiconductor structure DPS and the channel layer may be defined on the end of the channel pillar CHP.

Referring to FIGS. 3A and 3B, each of the plurality of conductive layers CDL and the plurality of interlayer insulating layers IL1, IL2, and IL3 may extend from the cell array area AR1 to the contact area AR2. Each of the plurality of conductive layers CDL and the plurality of interlayer insulating layers IL1, IL2, and IL3 may be penetrated by a plurality of gate contact plugs GCT in the contact area AR2.

Each gate contact plug GCT is a conductive pattern that contacts a corresponding conductive layer among the plurality of conductive layers CDL, and may be spaced apart from the remaining conductive layers by a sidewall insulating structure SWI. The gate contact plug GCT may include a contact portion CTP that contacts a corresponding conductive layer, and an extension portion EXP that extends from the contact portion CTP to penetrate the source-side insulating layer IL1. The contact portion CTP may be formed to be wider than the extension portion EXP. The sidewall insulating structure SWI may include a first sidewall insulation pattern SWI1 that encloses a sidewall of the contact portion CTP and a second sidewall insulation pattern SWI2 that encloses a sidewall of the extension portion EXP. An edge of the gate contact plug GCT may be defined in a width variable area between the contact portion CTP and the extension portion EXP. The conductive layer corresponding to the contact portion CTP may protrude laterally toward the edge of the gate contact plug GCT compared to the first sidewall insulation pattern SWI1, and form the contact surface with the contact portion CTP.

The peripheral circuit structure of the semiconductor memory device may include a plurality of transistors PTR. The peripheral circuit structure including the plurality of transistors PTR may be adjacent to the doped semiconductor structure DPS as illustrated in FIG. 3A, or be adjacent to the bit line array BAS as illustrated in FIG. 3B. Each transistor PTR may be disposed in an active area of a semiconductor substrate SUB partitioned by an isolation layer ISO.

The plurality of transistors PTR may include a first transistor TR1 that forms the pass circuit 40 described with reference to FIG. 1, and a second transistor TR2 that forms the page buffer 37 described with reference to FIG. 1. The first transistor TR1 may correspond to the pass transistor PT illustrated in FIG. 2. The first transistor TR1 and the second transistor TR2 may be covered with a peripheral insulating structure PIS on the semiconductor substrate SUB.

A plurality of interconnections IC may be disposed in the peripheral insulating structure PIS. The plurality of interconnections IC may include at least one of a plurality of conductive lines and a plurality of conductive contacts for electrical connection.

The first transistor TR1 may be coupled to the bit line BL via a corresponding interconnection IC, and the second transistor TR2 may be coupled to the gate contact plug GCT via a corresponding interconnection IC.

Referring to FIG. 3A, the doped semiconductor structure DPS may be disposed between the gate stacked body ST and the peripheral insulating structure PIS. The doped semiconductor structure DPS may be partitioned by an insulating structure SIS. The insulating structure SIS may be disposed between the contact area AR2 of the gate stacked body ST and the peripheral insulating structure PIS. The insulating structure SIS may be penetrated by a gate contact coupling structure GCC. The gate contact coupling structure GCC may electrically connect the extension portion EXP of the gate contact plug GCT to the interconnection IC connected to the second transistor TR2.

Referring to FIG. 3B, the bit line array BAS may be disposed between the gate stacked body ST and the peripheral insulating structure PIS. The contact area AR2 of the gate stacked body ST may include an area that is opened by the doped semiconductor structure DPS. The extension portion EXP of the gate contact plug GCT may penetrate the source-side interlayer insulating layer IL1 in the open area of the contact area AR2, and protrude beyond the gate stacked body ST. The contact portion CTP of the gate contact plug GCT may be coupled to a corresponding gate contact coupling structure GCC. The gate contact coupling structure GCC may include conductive patterns disposed on substantially the same level as the bit line coupling structure BCC and the bit line array BAS.

A plurality of first conductive bonding structures BP1 and a plurality of second conductive bonding structures BP2 may be disposed between the peripheral insulating structure PIS and a conductive group 90 including the gate contact coupling structure GCC, the bit line array BAS, and the bit line coupling structure BCC illustrated in FIG. 3B. The plurality of first conductive bonding structures BP1 may be disposed in the first intervening insulating structure IS1 between the conductive group 90 and the peripheral insulating structure PIS. Each of the plurality of bit lines BL and the gate contact coupling structure GCC may be coupled to a corresponding first conductive bonding structure BP1. The plurality of second conductive bonding structures BP2 may be disposed in the second intervening insulating structure IS2 between the first intervening insulating structure IS1 and the peripheral insulating structure PIS. Each of the plurality of second conductive bonding structures BP2 may be coupled to a corresponding interconnection IC. The plurality of second conductive bonding structures BP2 may be bonded to the plurality of first conductive bonding structures BP1. Thus, the gate contact coupling structure GCC may be electrically connected to the interconnection IC coupled to the first transistor TR1 via the first conductive bonding structure BP1 and the second conductive bonding structure BP2 corresponding thereto and bonded to each other. Further, each bit line BL may be electrically connected to the interconnection IC coupled to the second transistor TR2 via the first conductive bonding structure BP1 and the second conductive bonding structure BP2 corresponding thereto and bonded to each other.

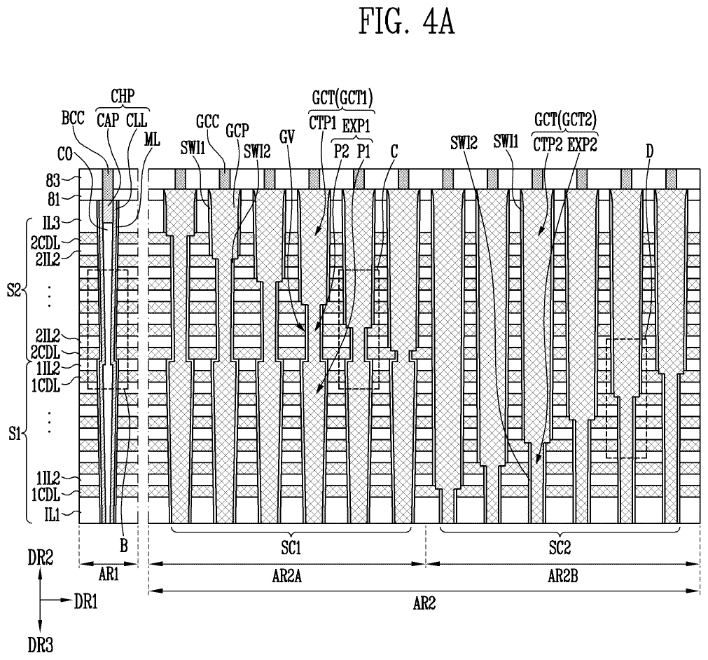

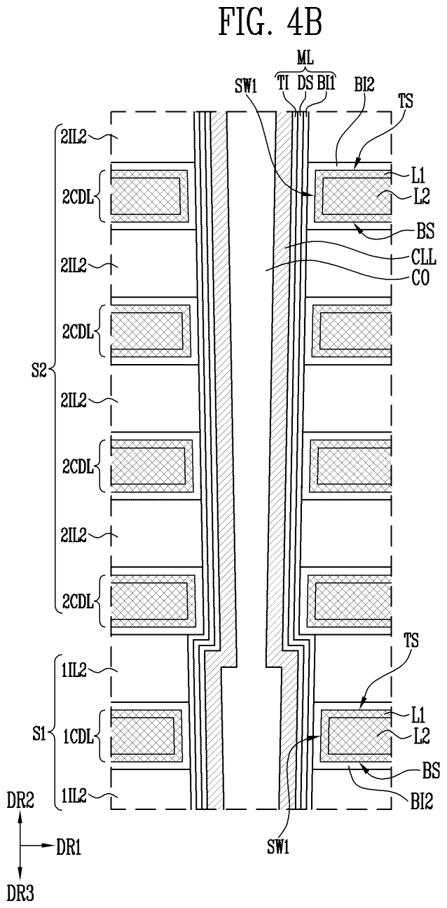

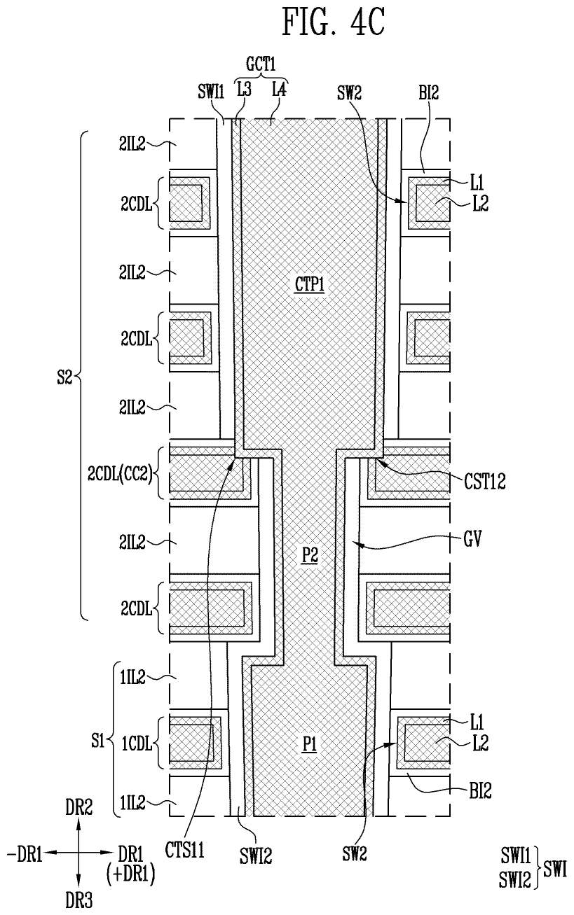

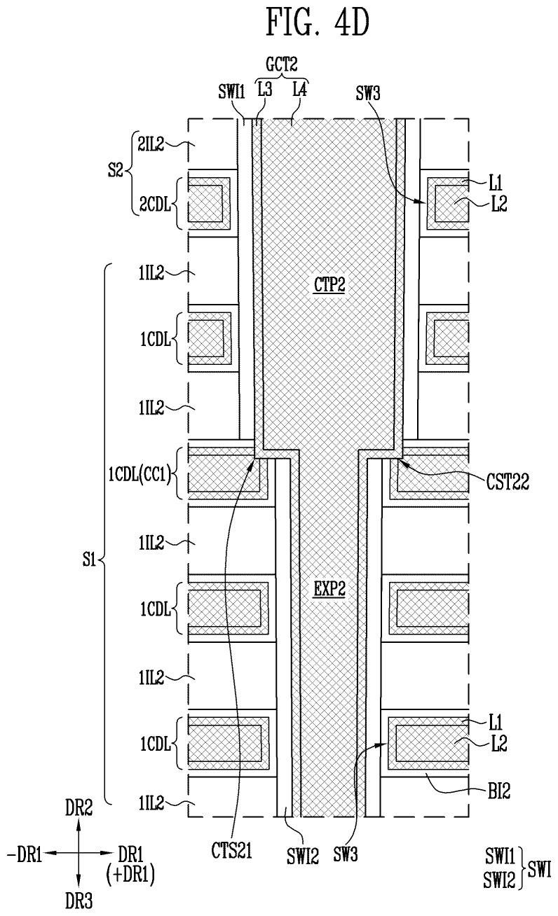

Referring to FIGS. 3A and 3B, the plurality of conductive layers CDL and the plurality of intervening interlayer insulating layers IL2 may be divided into two or more sub-stacked bodies, and the plurality of gate contact plugs GCT may be divided into two or more sub-contact sets corresponding to two or more sub-stacked bodies. Hereinafter, referring to FIGS. 4A to 4D, the present disclosure will be described based on an embodiment in which the plurality of conductive layers CDL and the plurality of intervening interlayer insulating layers IL2 are divided into a first sub-stacked body and a second sub-stacked body and the plurality of gate contact plugs GCT are divided into a first sub-contact set and a second sub-contact set.

FIGS. 4A to 4D are sectional views illustrating the cell array area and the contact area of a semiconductor memory device according to an embodiment of the present disclosure.

Referring to FIG. 4A, a gate stacked body ST described with reference to FIGS. 3A and 3B may include a first sub-stacked body S1 and a second sub-stacked body S2. Each of the first sub-stacked body S1 and the second sub-stacked body S2 may include a cell array area AR1 and a contact area AR2 extending from the cell array area AR1 in a first direction DR1. The contact area AR2 may include a first contact area AR2A and a second contact area AR2B that are adjacent to each other.

The first sub-stacked body S1 may include a source-side interlayer insulating layer IL1, a plurality of first intervening interlayer insulating layers 1IL2, and a plurality of first conductive layers 1CDL. The second sub-stacked body S2 may include a plurality of second conductive layers 2CDL, a plurality of second intervening interlayer insulating layers 2IL2, and a bit line-side interlayer insulating layer IL3. The plurality of first conductive layers 1CDL and the plurality of first intervening interlayer insulating layers 1IL2 may be alternately stacked layer by layer in a second direction DR2 over the source-side interlayer insulating layer IL1. The second direction DR2 may be defined as a direction intersecting a plane that extends in the first direction DR1. The plurality of second conductive layers 2CDL and the plurality of second intervening interlayer insulating layers 2IL2 may be alternately stacked layer by layer in the second direction DR2 over the first sub-stacked body S1.

A plurality of gate contact plugs GCT may include a plurality of first gate contact plugs GCT1 of a first sub-contact set SC1 and a plurality of second gate contact plugs GCT2 of a second sub-contact set SC2. The plurality of first gate contact plugs GCT1 may penetrate the first sub-stacked body S1 and the second sub-stacked body S2 in the first contact area AR2A. The plurality of second gate contact plugs GCT2 may penetrate the first sub-stacked body S1 and the second sub-stacked body S2 in the second contact area AR2B.

The first sub-contact set SC1 may include a plurality of first contact portions CTP1 of the plurality of first gate contact plugs GCT1 and a plurality of first extension portions EXP1 of the plurality of first gate contact plugs GCT1. The plurality of first extension portions EXP1 may include a plurality of first portions P1 and a plurality of second portions P2. Each first portion P1 may form a lower portion of a corresponding first gate contact plug GCT1, each second portion P2 may form a middle portion of the corresponding first gate contact plug GCT1, and each first contact portion CTP1 may form an upper portion of the corresponding first gate contact plug GCT1.

The plurality of first gate contact plugs GCT1 may be coupled to the plurality of second conductive layers 2CDL, respectively. The first contact portion CTP1 of the first gate contact plug GCT1 may contact a corresponding second conductive layer 2CDL so that each first gate contact plug GCT1 may be electrically connected to the corresponding second conductive layer 2CDL. The plurality of first contact portions CTP1 may be spaced apart from the plurality of first portions P1 in the second direction DR2. The plurality of first contact portions CTP1 may contact the plurality of second conductive layers 2CDL disposed on different layers, and may extend to different lengths in the second direction DR2. The second sub-stacked body S2 may be covered with a first insulating layer 81. The plurality of first contact portions CTP1 may protrude in the second direction DR2 beyond an interface between the second sub-stacked body S2 and the first insulating layer 81, and may penetrate the first insulating layer 81. The length of the plurality of first contact portions CTP1 in the second direction DR2 may increase as the plurality of first contact portions CTP1 approach the second sub-contact set SC2. In other words, the length of the plurality of first contact portions CTP1 may be in inverse proportion to a separation distance between the plurality of first contact portions CTP1 and the second sub-contact set SC2.

The plurality of first portions P1 of the plurality of first gate contact plugs GCT1 may penetrate the first sub-stacked body S1. The plurality of first portions P1 may be formed to have the substantially same length in the second direction DR2.

The plurality of second portions P2 of the plurality of first gate contact plugs GCT1 may extend from the plurality of first portions P1 in the second direction DR2. Each second portion P2 may extend from a corresponding first portion P1 toward the first contact portion CTP1. The length of the plurality of second portions P2 in the second direction DR2 may decrease as the plurality of second portions P2 approach the second sub-contact set SC2. In other words, the length of the plurality of second portions P2 may be in proportion to a separation distance between the plurality of second portions P2 and the second sub-contact set SC2.

The second sub-contact set SC2 may include a plurality of second contact portions CTP2 of the plurality of second gate contact plugs GCT2 and a plurality of second extension portions EXP2 of the plurality of second gate contact plugs GCT2. Each second extension portion EXP2 may form a lower portion of a corresponding second gate contact plug GCT2, and each second contact portion CTP2 may form an upper portion of the corresponding second gate contact plug GCT2.

The plurality of second gate contact plugs GCT2 may be coupled to the plurality of first conductive layers 1CDL, respectively. The second contact portion CTP2 of the second gate contact plug GCT2 may contact a corresponding first conductive layer 1CDL so that each second gate contact plug GCT2 may be electrically connected to the corresponding first conductive layer 1CDL. The plurality of second contact portions CTP2 may contact the plurality of first conductive layers 1CDL disposed on different layers, respectively, and may extend to different lengths in the second direction DR2. The plurality of second contact portions CTP2 may penetrate the second sub-stacked body S2 and the first insulating layer 81. The length of the plurality of second contact portions CTP2 in the second direction DR2 may increase as the plurality of second contact portions CTP2 approach the first sub-contact set SC1. In other words, the length of the plurality of second contact portions CTP2 may be in inverse proportion to a separation distance between the plurality of second contact portions CTP2 and the first sub-contact set SC1.

The plurality of second extension portions EXP2 of the plurality of second gate contact plugs GCT2 may extend from the plurality of second contact portions CTP2 to different lengths in a third direction DR3. The third direction DR3 may be defined as a direction opposite to the second direction DR2. Each second extension portion EXP2 may extend from a corresponding second contact portion CTP2 to penetrate the source-side interlayer insulating layer IL1. The length of the plurality of second extension portions EXP2 in the second direction DR2 may decrease as the plurality of second extension portions EXP2 approach the first sub-contact set SC1. In other words, the length of the plurality of second extension portions EXP2 may be in proportion to a separation distance between the plurality of second extension portions EXP2 and the first sub-contact set SC1.

A sidewall of each of the first contact portion CTP1 and the second contact portion CTP2 may be enclosed by a first sidewall insulation pattern SWI1. A sidewall of each of the first extension portion EXP1 and the second extension portion EXP2 may be enclosed by a second sidewall insulation pattern SWI2.

In the cell array area AR1, the first sub-stacked body S1 and the second sub-stacked body S2 may be penetrated by the channel pillar CHP. The channel pillar CHP may include a channel layer CLL extending to penetrate the first sub-stacked body S1 and the second sub-stacked body S2. The channel layer CLL may be formed of a semiconductor material such as silicon (Si), germanium (Ge), or a mixture thereof, which may be used as the channel area of the memory cell string. The channel layer CLL may be formed in a tubular structure. In this case, the channel pillar CHP may further include a core insulating layer CO and a capping pattern CAP disposed in a central area of the tubular structure formed as the channel layer CLL. The capping pattern CAP may include a doped semiconductor layer containing at least one of the n-type impurity and the p-type impurity. According to an embodiment, the capping pattern CAP may include n-type doped silicon containing the n-type impurity as the majority carrier.

A memory layer ML may be disposed between each of the first sub-stacked body S1 and the second sub-stacked body S2 and the channel layer CLL.

The first insulating layer 81 may be covered with a second insulating layer 83. The first insulating layer 81 and the second insulating layer 83 may be penetrated by the bit line coupling structure BCC. The bit line coupling structure BCC may be coupled to the capping pattern CAP.

The plurality of gate contact plugs GCT may be coupled, respectively, to the plurality of conductive patterns penetrating the second insulating layer 83. According to an embodiment, each of the conductive patterns penetrating the second insulating layer 83 may serve as the gate contact coupling structure GCC described with reference to FIG. 3B.

FIG. 4B is an enlarged view of area “B” illustrated in FIG. 4A.

Referring to FIGS. 4A and 4B, the channel layer CLL and the core insulating layer CO may be enclosed by the plurality of first intervening interlayer insulating layers 1IL2 and the plurality of first conductive layers 1CDL of the first sub-stacked body S1, and the plurality of second intervening interlayer insulating layers 2IL2 and the plurality of second conductive layers 2CDL of the second sub-stacked body S2.

The memory layer ML may include a tunnel insulating layer TI, a data storage layer DS, and a first blocking insulating layer BI1. The tunnel insulating layer TI may extend along an outer wall of the channel layer CLL. The tunnel insulating layer TI may include an insulating material such as a silicon oxide layer. The data storage layer DS may be interposed between each of the first sub-stacked body S1 and the second sub-stacked body S2 and the tunnel insulating layer TI. The data storage layer DS may extend continuously along an outer wall of the tunnel insulating layer TI. An embodiment of the present disclosure is not limited thereto. Although not illustrated in the drawing, according to an embodiment, the data storage layer DS may be divided into a plurality of data storage patterns spaced apart from each other in the second direction DR2, and the plurality of data storage patterns may be disposed at levels where the plurality of first conductive layers 1CDL and the plurality of second conductive layers 2CDL are disposed. The data storage pattern DS may be formed of a material layer that may store changed data using Fowler-Nordheim tunneling. According to an embodiment, the data storage pattern DS may be formed of a charge trap insulating layer, a floating gate layer, or an insulating layer containing conductive nanodots. The charge trap insulating layer may include a silicon nitride layer. The first blocking insulating layer BI1 may be interposed between each of the first sub-stacked body S1 and the second sub-stacked body S2 and the data storage layer DS. The first blocking insulating layer BI1 may include at least one of a silicon dioxide layer (SiO₂) and a high-k dielectric layer having a higher dielectric constant than the silicon dioxide layer. The high-k dielectric layer may include an aluminum oxide layer, a hafnium oxide layer or the like.

Each of the first conductive layer 1CDL and the second conductive layer 2CDL may be formed of various conductive materials. According to an embodiment, each of the first conductive layer 1CDL and the second conductive layer 2CDL may include a barrier layer L1 and a metal layer L2. The barrier layer L1 may include a conductive metal nitride layer such as titanium nitride or tantalum nitride, as described with reference to FIGS. 3A and 3B. The metal layer L2 may contain tungsten or the like. The barrier layer L1 may extend from between each of the first intervening interlayer insulating layer 1IL2 and the second intervening interlayer insulating layer 2IL2 and the metal layer L2 to between the memory layer ML and the metal layer L2.

Each of the first conductive layer 1CDL and the second conductive layer 2CDL may include a top surface TS facing the second direction DR2, a bottom surface BS facing the third direction DR3, and a first sidewall SW1 facing the channel layer CLL. The second blocking insulating layer BI2 may extend along the top surface TS, the bottom surface BS, and the first sidewall SW1 of each of the first conductive layer 1CDL and the second conductive layer 2CDL. The second blocking insulating layer BI2 may include a high-k dielectric layer such as an aluminum oxide layer.

At least one of the first blocking insulating layer BI1 and the second blocking insulating layer BI2 may be omitted.

FIG. 4C is an enlarged view of area “C” illustrated in FIG. 4A.

Referring to FIGS. 4A and 4C, the plurality of first intervening interlayer insulating layers 1IL2 and the plurality of first conductive layers 1CDL of the first sub-stacked body S1 and the plurality of second intervening interlayer insulating layers 2IL2 and the plurality of second conductive layers 2CDL of the second sub-stacked body S2 may extend to the first contact area AR2A. The barrier layer L1 and the metal layer L2 of each of the first conductive layer 1CDL and the second conductive layer 2CDL may extend from the cell array area AR1 to the first contact area AR2A. Each of the first conductive layer 1CDL and the second conductive layer 2CDL may further include a second sidewall SW2 facing the first gate contact plug GCT1.

The second blocking insulating layer BI2 may extend from the cell array area AR1 to the first contact area AR2A. The second blocking insulating layer BI2 may extend between the second sidewall SW2 of each of the first conductive layer 1CDL and the second conductive layer 2CDL and the first gate contact plug GCT1.

The first gate contact plug GCT1 may be formed of various conductive materials. According to an embodiment, the first gate contact plug GCT1 may include a barrier layer L3 and a metal layer L4. The barrier layer L3 may include a conductive metal nitride layer such as titanium nitride or tantalum nitride. The metal layer L4 may contain tungsten or the like. The barrier layer L3 may extend along an outer wall of the metal layer L4.

The first gate contact plug GCT1 may have a width defined in the first direction DR1. The width of the first gate contact plug GCT1 may vary at a boundary between the first portion P1, the second portion P2, and the first contact portion CTP1. The second portion P2 may be formed to be narrower than each of the first portion P1 and the first contact portion CTP1. Thus, a groove GV may be defined between the first contact portion CTP1 and the first portion P1. The first contact portion CTP1 may include protrusions protruding on both sides of the second portion P2. The protrusion of the first contact portion CTP1 may form a first contact surface with a corresponding second conductive layer CC2 among the plurality of second conductive layers 2CDL. For example, as shown in FIG. 4C, the first contact portion CTP1 may have a first protrusion protruding toward the second conductive layer CC2 in the direction opposite (i.e., negative first direction −DR1) to the first direction DR1 and a second protrusion protruding toward the second conductive layer CC2 in the first direction DR1 (i.e., positive first direction +DR1). In an embodiment, the first protrusion of the first contract portion CTP1 may form a first contact surface CTS11 with the second conductive layer CC2 as shown in FIG. 4C. In an embodiment, the second protrusion of the first contract portion CTP1 may form another first contact surface CTS12 with the second conductive layer CC2 as shown in FIG. 4C.

The first sidewall insulation pattern SWI1 and the second sidewall insulation pattern SWI2 of the sidewall insulating structure SWI corresponding to the first gate contact plug GCT1 may be spaced apart from each other by each of the first contact surfaces CTS11 and CTS12. The first sidewall insulation pattern SWI1 may enclose an upper sidewall of the first contact portion CTP1 protruding beyond each of the first contact surfaces CTS11 and CTS12 in the second direction DR2. The second sidewall insulation pattern SWI2 may enclose a sidewall of the first portion P1, and may extend to enclose a sidewall of the second portion P2.

FIG. 4D is an enlarged view of area “D” illustrated in FIG. 4A.

Referring to FIGS. 4A and 4D, the plurality of first intervening interlayer insulating layers 1IL2 and the plurality of first conductive layers 1CDL of the first sub-stacked body S1 and the plurality of second intervening interlayer insulating layers 2IL2 and the plurality of second conductive layers 2CDL of the second sub-stacked body S2 may extend to the second contact area AR2B. The barrier layer L1 and the metal layer L2 of each of the first conductive layer 1CDL and the second conductive layer 2CDL may extend from the cell array area AR1 to the second contact area AR2B. Each of the first conductive layer 1CDL and the second conductive layer 2CDL may further include a third sidewall SW3 facing the second gate contact plug GCT2. The second blocking insulating layer BI2 may extend from the cell array area AR1 to the second contact area AR2B. The second blocking insulating layer BI2 may extend between the second gate contact plug GCT2 and the third sidewall SW3 of each of the first conductive layer 1CDL and the second conductive layer 2CDL.

Similarly to the first gate contact plug GCT1, the second gate contact plug GCT2 may include a barrier layer L3 and a metal layer L4.

The second gate contact plug GCT2 may have a width defined in the first direction DR1. The width of the second gate contact plug GCT2 may vary at a boundary between the second extension portion EXP2 and the second contact portion CTP2. The second extension portion EXP2 may be formed to be narrower than the second contact portion CTP2. The second contact portion CTP2 may include protrusions protruding on both sides of the second extension portion EXP2. The protrusion of the second contact portion CTP2 may form a second contact surface with a corresponding first conductive layer CC1 among the plurality of first conductive layers 1CDL. For example, as shown in FIG. 4D, the second contact portion CTP2 may have a first protrusion protruding toward the first conductive layer CC1 in the direction opposite (i.e., negative first direction −DR1) to the first direction DR1 and a second protrusion protruding toward the first conductive layer CC1 in the first direction DR1 (i.e., positive first direction +DR1). In an embodiment, the first protrusion of the second contract portion CTP2 may form a second contact surface CTS21 with the first conductive layer CC1 as shown in FIG. 4D. In an embodiment, the second protrusion of the second contract portion CTP2 may form another second contact surface CTS22 with the first conductive layer CC1 as shown in FIG. 4D.

The first sidewall insulation pattern SWI1 and the second sidewall insulation pattern SWI2 of the sidewall insulating structure SWI corresponding to the second gate contact plug GCT2 may be spaced apart from each other by each of the second contact surfaces CTS21 and CTS22. The first sidewall insulation pattern SWI1 may enclose an upper sidewall of the second contact portion CTP2 protruding beyond each of the second contact surfaces CTS21 and CTS22 in the second direction DR2. The second sidewall insulation pattern SWI2 may enclose a sidewall of the second extension portion EXP2.

The gate contact plug according to an embodiment of the present disclosure can simplify a coupling structure between the transistor (e.g. TR1 illustrated in FIG. 3A or 3B) of the peripheral circuit structure and the gate contact plug, by penetrating the stacked body of the conductive layers.

According to an embodiment of the present disclosure, the gate contact plug includes a contact portion that is in contact with a corresponding conductive layer and the contact portion is relatively wide, thus reducing the difficulty of a manufacturing process for providing the contact surface between the contact portion and the conductive layer.

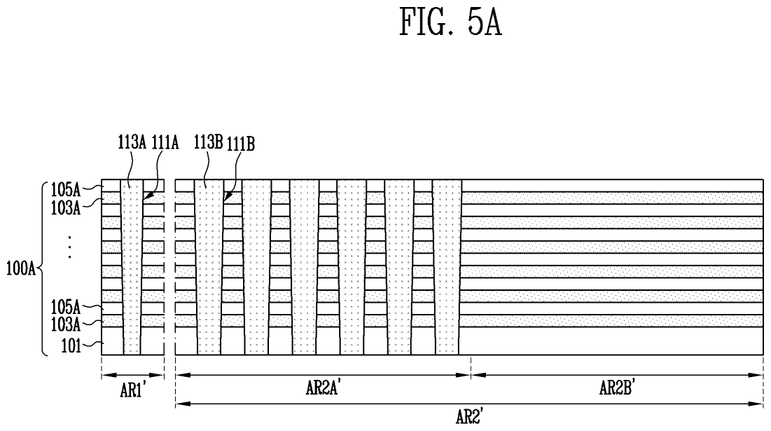

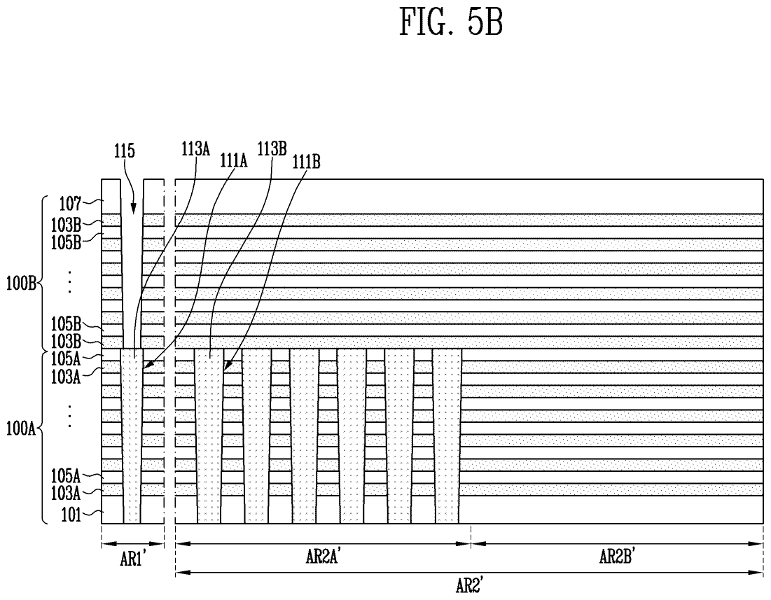

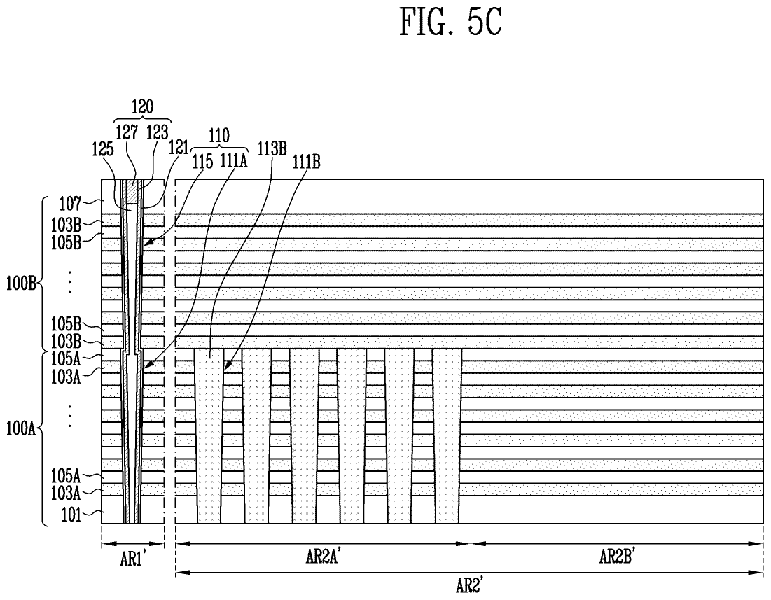

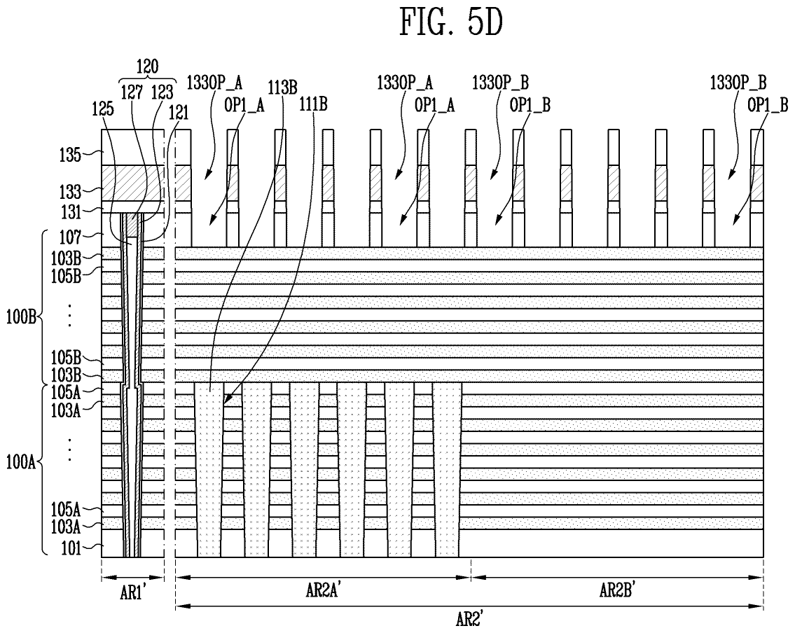

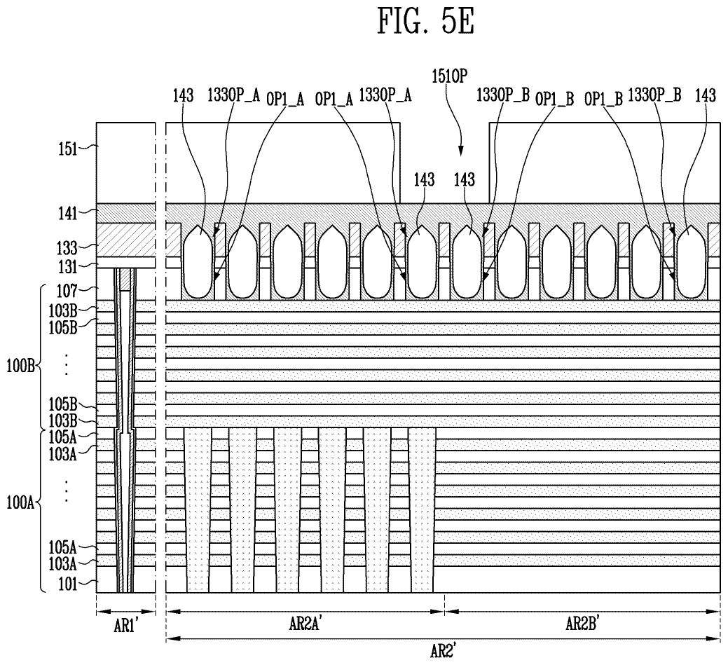

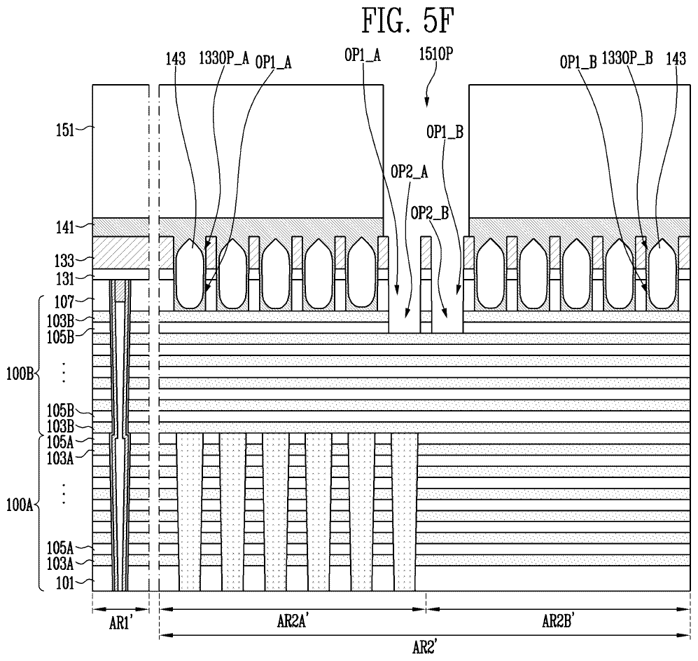

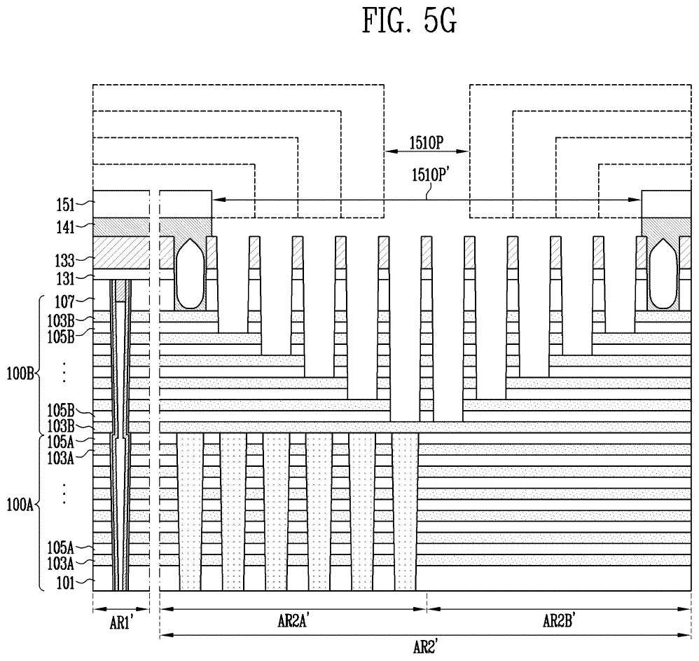

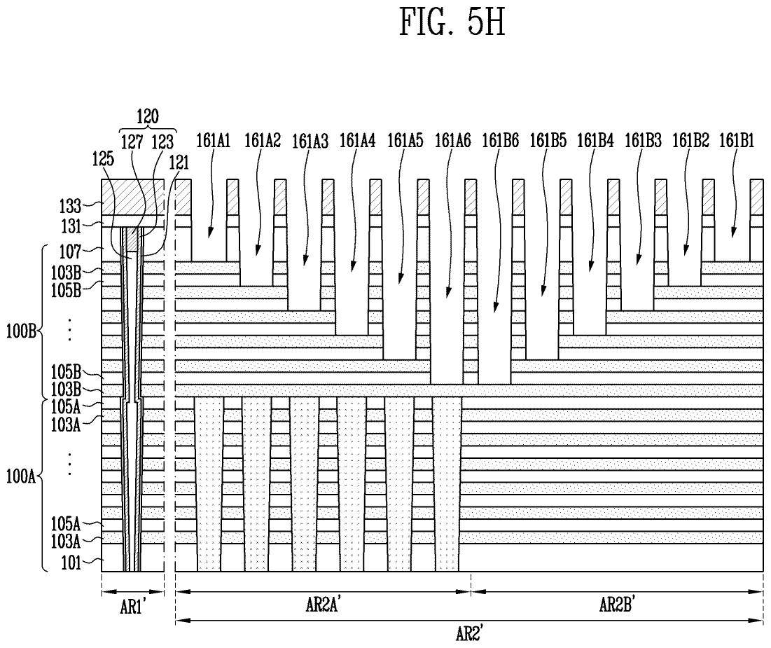

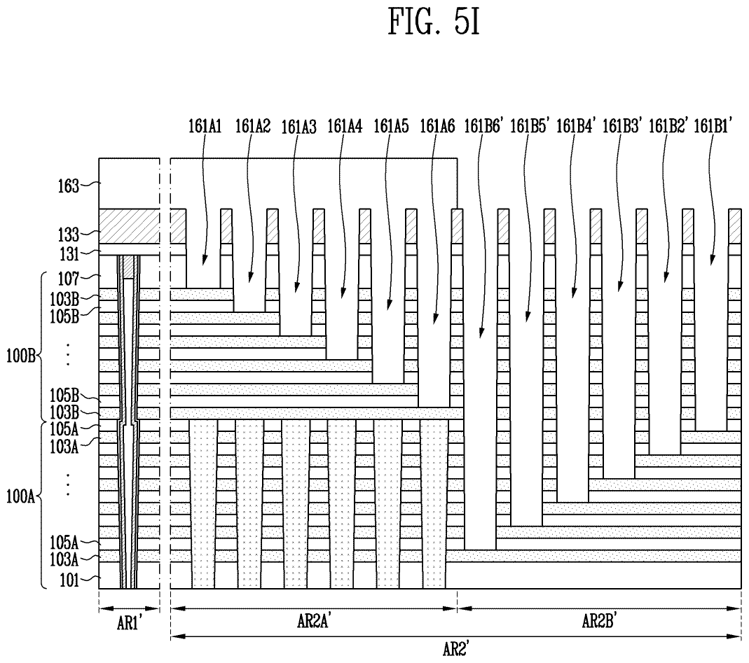

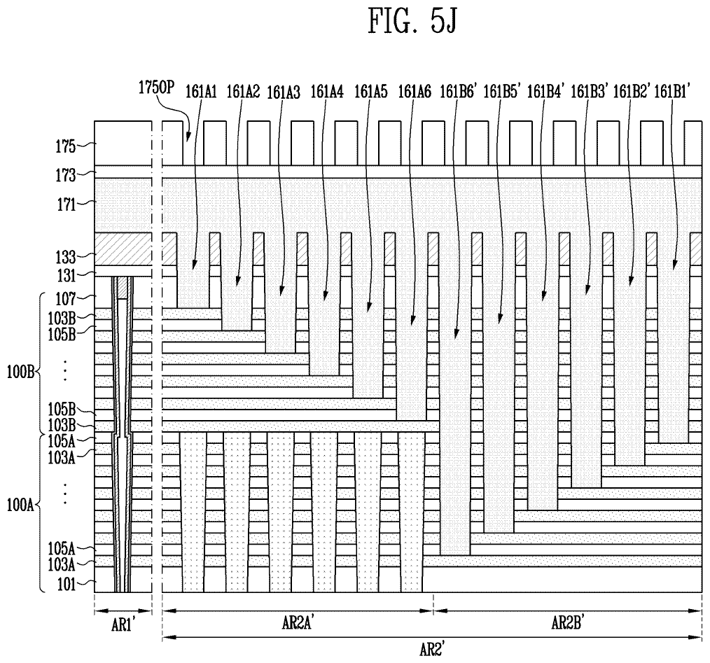

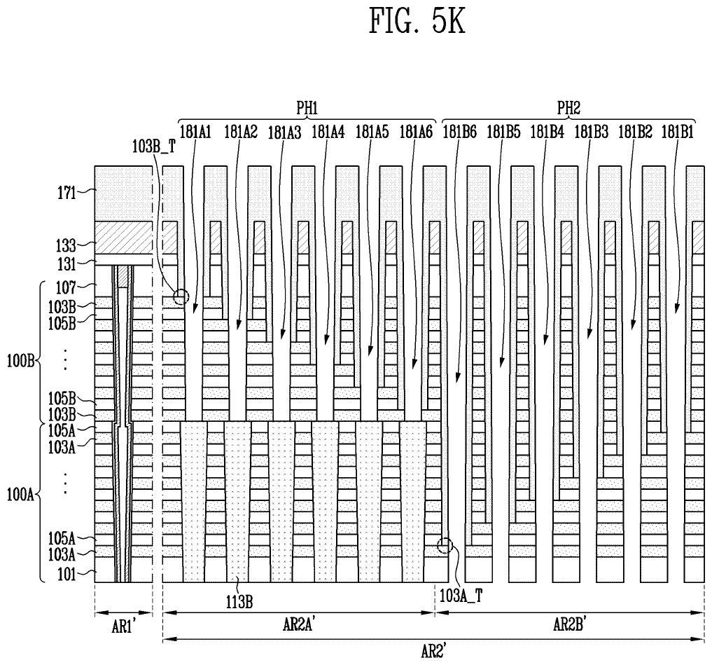

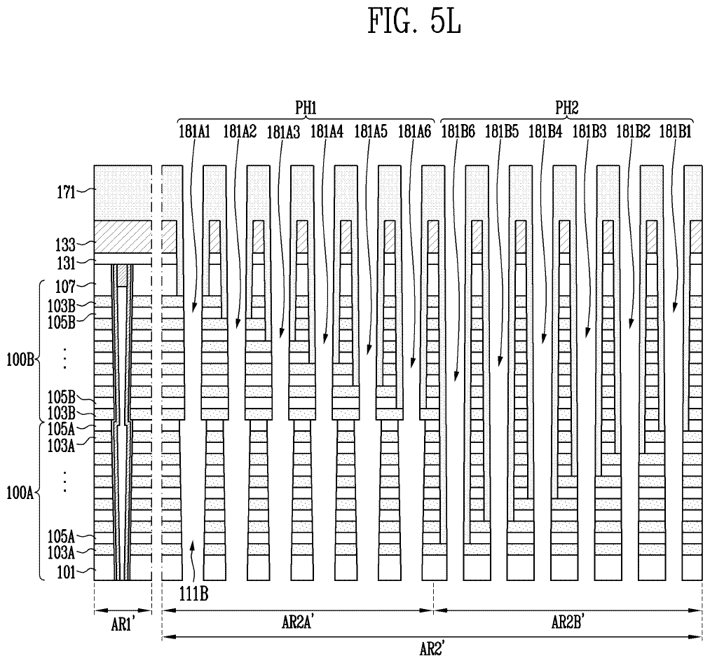

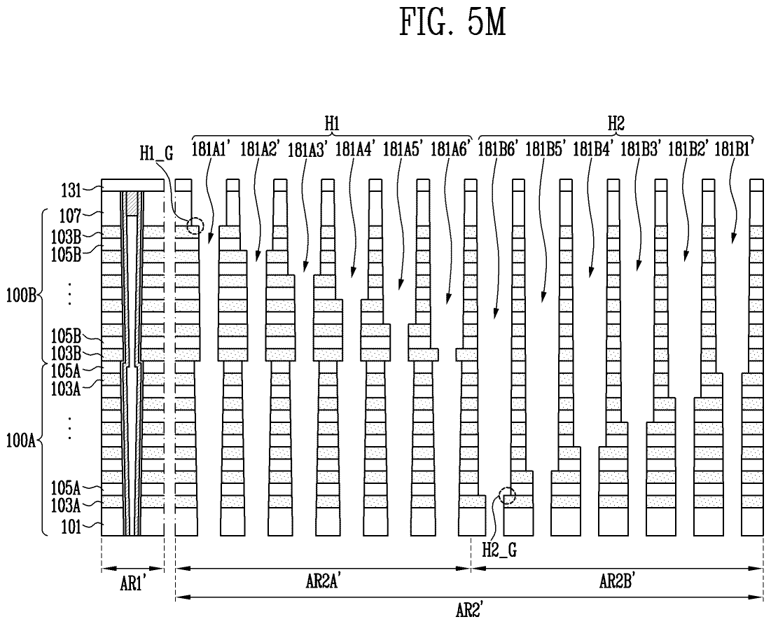

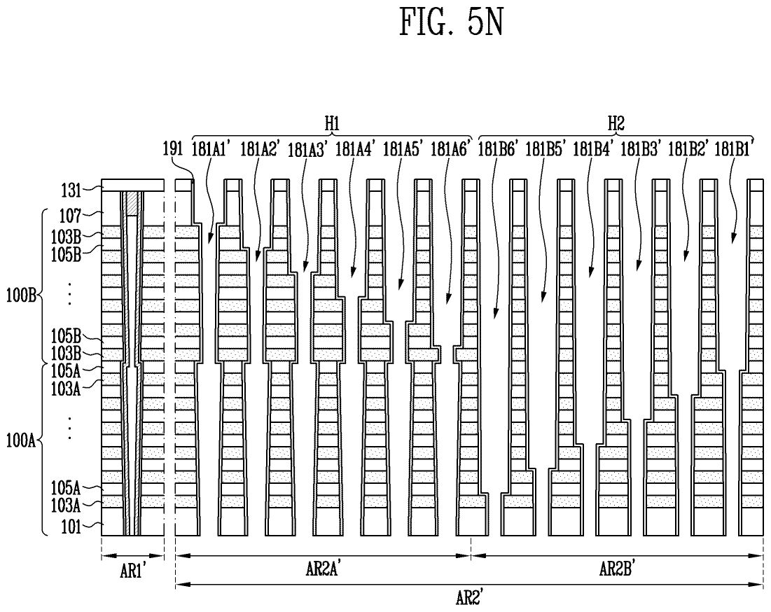

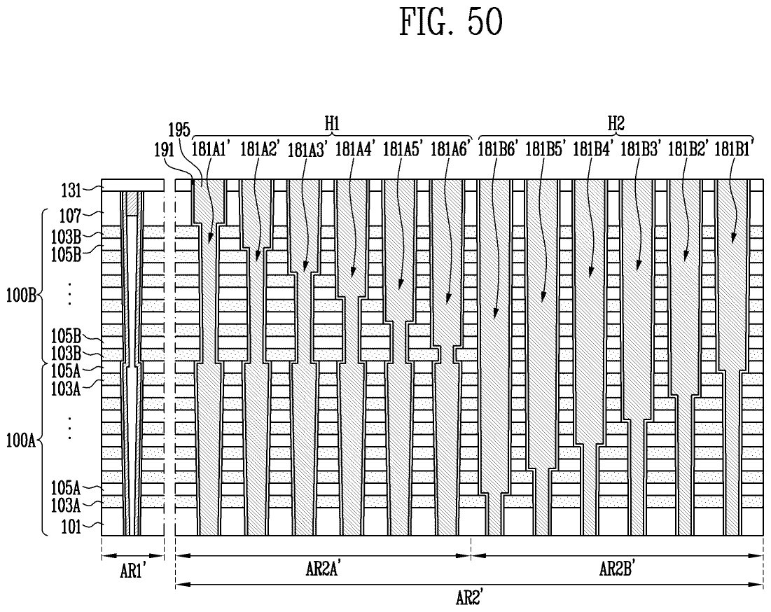

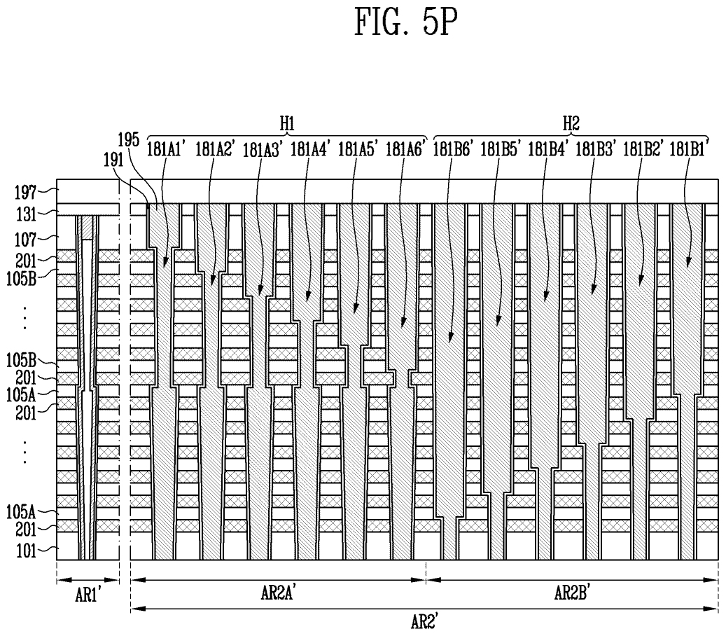

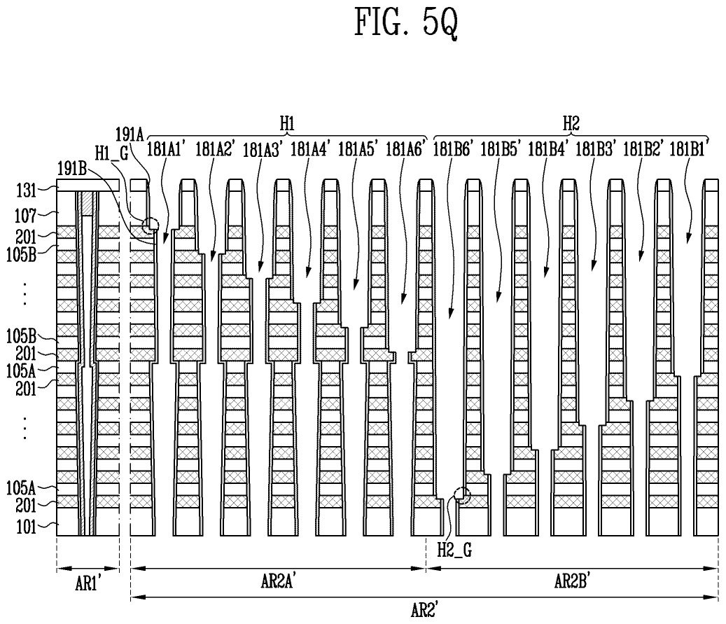

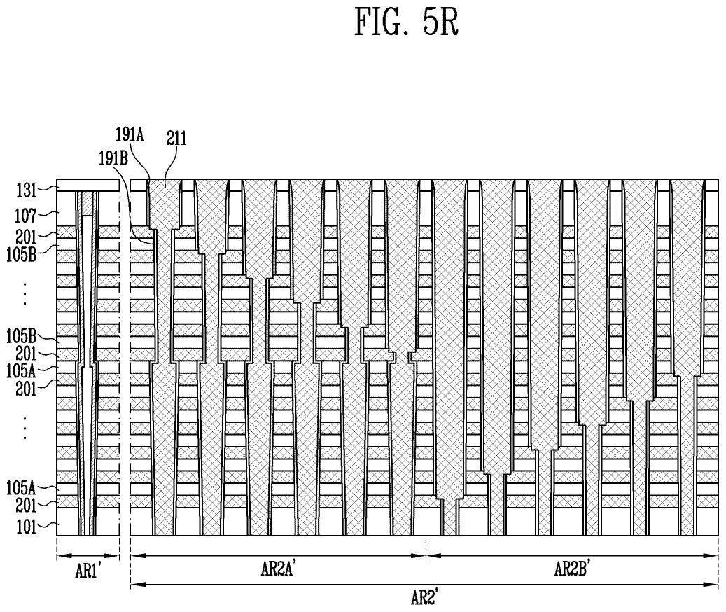

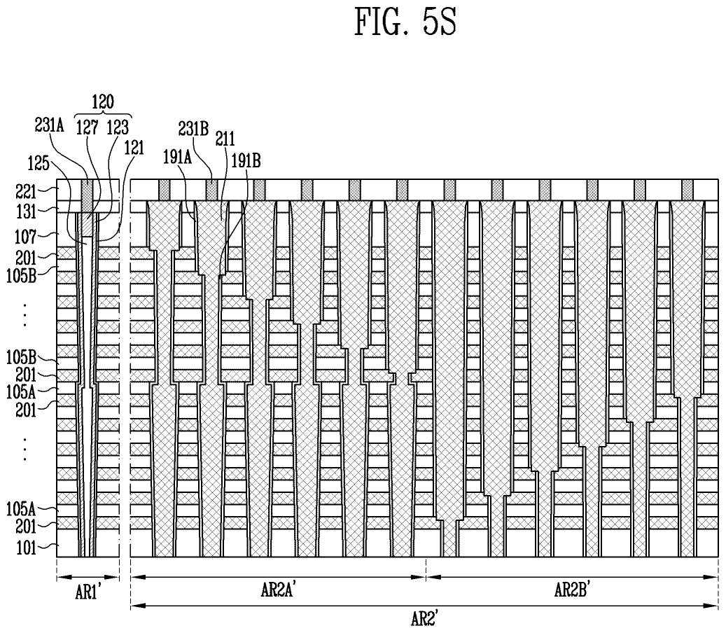

FIGS. 5A to 5S are sectional views illustrating a method of manufacturing a semiconductor memory device according to an embodiment of the present disclosure.

Referring to FIG. 5A, a first stacked body 100A may be formed over a lower structure (not illustrated). Although not illustrated in the drawing, according to an embodiment, the lower structure may include a semiconductor substrate SUB including the plurality of transistors PTR illustrated in FIG. 3A and the doped semiconductor structure DPS illustrated in FIG. 3A. According to an embodiment, the lower structure may be a sacrificial substrate formed of a silicon wafer or the like.

The first stacked body 100A may include a first area AR1′ and a second area AR2′ extending from the first area AR1′. The first area AR1′ may correspond to the cell array area AR1 illustrated in FIG. 4A. The second area AR2′ may correspond to the contact area AR2 illustrated in FIG. 4A. The second area AR2′ may include a first sub-area AR2A′ and a second sub-area AR2B′ that are adjacent to each other. The first sub-area AR2A′ and the second sub-area AR2B′ may correspond to the first contact area AR2A and the second contact area AR2B illustrated in FIG. 4A, respectively.

The first stacked body 100A may include a lower interlayer insulating layer 101, and a plurality of first sacrificial layers 103A and a plurality of first interlayer insulating layers 105A that are alternately disposed over the lower interlayer insulating layer 101 in a stacking direction. The plurality of first sacrificial layers 103A may be formed of a material having an etch selectivity with respect to the lower interlayer insulating layer 101 and the plurality of first interlayer insulating layers 105A. According to an embodiment, the lower interlayer insulating layer 101 and the plurality of first interlayer insulating layers 105A may include an insulating material such as a silicon oxide layer or a silicon oxynitride layer, and the plurality of first sacrificial layers 103A may include a sacrificial insulating material such as a silicon nitride layer.

Subsequently, by etching the first stacked body 100A using a first mask pattern (not illustrated) as an etch barrier, a lower channel hole 111A and a plurality of first openings 111B may be formed in the first stacked body 100A. The lower channel hole 111A and the plurality of first openings 111B may be simultaneously formed and may extend to pass through the lower interlayer insulating layer 101, the plurality of first sacrificial layers 103A, and the plurality of first interlayer insulating layers 105A of the first stacked body 100A. The lower channel hole 111A may pass through the first stacked body 100A in the first area AR1′, and the plurality of first openings 111B may pass through the first stacked body 100A in the first sub-area AR2A′ of the second area AR2′.

Thereafter, a first filling layer may be formed to fill the inside of the lower channel hole 111A and the plurality of first openings 111B, and the first filling layer may planarize so that the first filling layer is separated into a cell sacrificial pillar 113A and a plurality of sacrificial pillars 113B. Although not illustrated in the drawing, an air gap may be formed inside the first filling layer. The first filling layer may include a material having an etch selectivity to the lower interlayer insulating layer 101, the plurality of first sacrificial layers 103A, and the plurality of first interlayer insulating layers 105A. According to an embodiment, the first filling layer may include an amorphous carbon layer. The planarization of the first filling layer may be performed using chemical mechanical polishing (CMP). The cell sacrificial pillar 113A may be disposed in the lower channel hole 111A, and the plurality of sacrificial pillars 113B may be disposed in the plurality of first openings 111B, respectively. The first mask pattern (not illustrated) may be removed during the process of forming the cell sacrificial pillar 113A and the plurality of sacrificial pillars 113B or may be removed through a separate removal process.

Referring to FIG. 5B, a second stacked body 100B may be formed over the first stacked body 100A. The second stacked body 100B may include a plurality of second sacrificial layers 103B and a plurality of second interlayer insulating layers 105B that are alternately disposed over the first stacked body 100A in a stacking direction, and a third interlayer insulating layer 107 disposed over the uppermost second sacrificial layer among the plurality of second sacrificial layers 103B. The plurality of second sacrificial layers 103B may be formed of the same material as the plurality of first sacrificial layers 103A, and the plurality of second interlayer insulating layers 105B and the third interlayer insulating layer 107 may be formed of the same material as the plurality of first interlayer insulating layers 105A.

Subsequently, by etching the second stacked body 100B using a second mask pattern (not illustrated) as an etch barrier, an upper channel hole 115 may be formed in the second stacked body 100B. The upper channel hole 115 may pass through the plurality of second sacrificial layers 103B of the second stacked body 100B, the plurality of second interlayer insulating layers 105B, and the third interlayer insulating layer 107 to allow the cell sacrificial pillar 113A to be exposed by the upper channel hole 115.

Referring to FIG. 5C, the cell sacrificial pillar 113A illustrated in FIG. 5B may be selectively removed through the upper channel hole 115. Thus, the upper channel hole 115 and the lower channel hole 111A may be coupled to define a channel hole 110.

Subsequently, a memory layer 121 may be formed along an inner wall of the channel hole 110. The memory layer 121 may include a first blocking insulating layer BI1, a data storage layer DS, and a tunnel insulating layer TI illustrated in FIG. 4B. Thereafter, the channel pillar 120 may be formed in the central area of the channel hole 110 that is opened by the memory layer 121.

According to an embodiment, a step of forming the channel pillar 120 may include a step of forming the channel layer 123 along the inner wall of the memory layer 121, and a step of filling a central are of a tubular structure defined by the channel layer 123 with the core insulating layer 125 and the capping pattern 127. The channel layer 123 may be formed of a semiconductor material that may be used for the channel area, such as silicon (Si), germanium (Ge) or a mixture thereof. The capping pattern 127 may be formed of the doped semiconductor layer. The second mask pattern (not illustrated) may be removed during the process of forming the channel pillar 120 or may be removed through a separate removal process.

Referring to FIG. 5D, the first insulating layer 131 may be formed over the second stacked body 100B to overlap the channel pillar 120. The first insulating layer 131 may include a silicon oxide layer or the like.

Subsequently, a third mask pattern 133 may be formed over the first insulating layer 131. The third mask pattern 133 may include a material having etch selectivity to the first stacked body 100A, the second stacked body 100B, and the first insulating layer 131. According to an embodiment, the third mask pattern 133 may include silicon.

The third mask pattern 133 may include a plurality of openings 133OP_A and 133OP_B defined by an etching process using a first photoresist pattern 135 as an etch barrier. The width of each of the plurality of openings 133OP_A and 133OP_B may be formed to be wider than that of each of the plurality of sacrificial pillars 113B. The plurality of openings 133OP_A and 133OP_B may include a plurality of first type openings 133OP_A and a plurality of second type openings 133OP_B. The plurality of first type openings 133OP_A may overlap the plurality of sacrificial pillars 113B, respectively. The plurality of second type openings 133OP_B may overlap the first stacked body 100A in the second sub-area AR2B′.

A plurality of primary second openings OP1_A and OP1_B may be formed by etching the first insulating layer 131 and the third interlayer insulating layer 107 that are exposed by the plurality of first type openings 133OP_A and the plurality of second type openings 133OP_B. The plurality of primary second openings OP1_A and OP1_B may pass through the first insulating layer 131 and pass through the third interlayer insulating layer 107 of the second stacked body 100B. The plurality of primary second openings OP1_A and OP1_B may be divided into a first group OP1_A and a second group OP1_B. The plurality of primary second openings OP1_A of the first group may correspond to the plurality of first type openings 133OP_A, respectively, and overlap the plurality of sacrificial pillars 113B, respectively. The plurality of primary second openings OP1_B of the second group may correspond to the plurality of second type openings 133OP_B, respectively, and overlap the second sub-area AR2B′ of the first stacked body 100A.

Referring to FIG. 5E, the first photoresist pattern 135 illustrated in FIG. 5D may be removed. Subsequently, the second filling layer 141 may be formed. The second filling layer 141 may be formed inside the plurality of openings 133OP_A and 133OP_B of the third mask pattern 133 and may extend into the plurality of primary second openings OP1_A and OP1_B defined in each of the first insulating layer 131 and the third interlayer insulating layer 107. The second filling layer 141 may include a material having etch selectivity to the first stacked body 100A, the second stacked body 100B, the first insulating layer 131, and the third mask pattern 133. According to an embodiment, the second filling layer 141 may include an amorphous carbon layer. The second filling layer 141 may be formed using a deposition method with low step coverage. Thus, a void 143 may be formed in the second filling layer 141.

Subsequently, a second photoresist pattern 151 may be formed over the second filling layer 141. The second photoresist pattern 151 may include an opening 151OP. The opening 151OP of the second photoresist pattern 151 may expose the first area of the second filling layer 141. The first area of the second filling layer 141 may include a portion of the second filling layer 141 disposed in the primary second opening OP1_A of the first group and the primary second opening OP1_B of the second group, which are adjacent to each other, among the plurality of primary second openings OP1_A and OP1_B.

Referring to FIG. 5F, the first area of the second filling layer 141 exposed by the opening 151OP of the second photoresist pattern 151 may be removed. Thus, the uppermost second sacrificial layer among the plurality of second sacrificial layers 103B may be exposed through the primary second opening OP1_A of the first group and the primary second opening OP1_B of the second group, which are adjacent to each other. Subsequently, by etching the exposed uppermost second sacrificial layer and the second interlayer insulating layer 105B located thereunder, the depth of the primary second opening OP1_A of the first group and the primary second opening OP1_B of the second group, which are adjacent to each other, may become deeper, and a secondary second opening OP2_A of the first group and a secondary second opening OP2_B of the second group may be defined. The uppermost second sacrificial layer may be penetrated by the secondary second opening OP2_A of the first group and the secondary second opening OP2_B of the second group, and a second sacrificial layer in another layer adjacent to the uppermost second sacrificial layer may be exposed.

Referring to FIG. 5G, an etching process in which the size of the second photoresist pattern 151 is reduced so that the width of the opening 151OP of the second photoresist pattern 151 is sequentially increased until the lowermost second sacrificial layer among the plurality of second sacrificial layers 103B is exposed, and an etching process of the plurality of second sacrificial layers 103B and the plurality of second interlayer insulating layers 105B of the second stacked body 100B may be repeated. When the lowermost second sacrificial layer is exposed, the remaining second photoresist pattern 151 may include an expanded opening 151OP′ having an expanded width compared to the opening 151OP. Referring to FIG. 5H, the second photoresist pattern 151 and the second filling layer 141 illustrated in FIG. 5G may be removed. A plurality of first type second openings 161A1 to 161A6 and a plurality of preliminary openings 161B1 to 161B6 may be defined through a series of processes described with reference to FIGS. 5D to 5H.

The plurality of first type second openings 161A1 to 161A6 may be formed in the second stacked body 100B, and may overlap the plurality of sacrificial pillars 113B, respectively. The plurality of first type second openings 161A1 to 161A6 may expose the plurality of second sacrificial layers 103B, respectively. The bottom surface of each of the plurality of first type second openings 161A1 to 161A6 may be defined by the top surface of a corresponding second sacrificial layer among the plurality of second sacrificial layers 103B.

The plurality of preliminary openings 161B1 to 161B6 may be formed in the second stacked body 100B and overlap the second sub-area AR2B′ of the first stacked body 100A. The plurality of preliminary openings 161B1 to 161B6 may expose the plurality of second sacrificial layers 103B, respectively. The bottom surface of each of the plurality of preliminary openings 161B1 to 161B6 may be defined by the top surface of a corresponding second sacrificial layer among the plurality of second sacrificial layers 103B. The plurality of preliminary openings 161B1 to 161B6 may be mirror symmetrical to the plurality of first type second openings 161A1 to 161A6.

Referring to FIG. 5I, a third photoresist pattern 163 may be formed over the third mask pattern 133. The third photoresist pattern 163 may block the plurality of first type second openings 161A1 to 161A6 and include an opening that exposes the plurality of preliminary openings 161B1 to 161B6 illustrated in FIG. 5H.

A portion of the second stacked body 100B and a portion of the first stacked body 100A overlapping the plurality of preliminary openings 161B1 to 161B6 (see FIG. 5H) opened by the third photoresist pattern 163 may be etched through the preliminary openings. Thus, the second type of second openings 161B1′ to 161B6′ may be formed.

The second type of second openings 161B1′ to 161B6′ may pass through the second stacked body 100B and extend into the first stacked body 100A. The plurality of second type second openings 161B1′ to 161B6′ may expose the plurality of first sacrificial layers 103A, respectively. The bottom surface of each of the plurality of second type second openings 161B1′ to 161B6′ may be defined by the top surface of a corresponding first sacrificial layer among the plurality of first sacrificial layers 103A.

Referring to FIG. 5J, after removing the third photoresist pattern 163 illustrated in FIG. 5I, a lower mask layer 171 and an upper mask layer 173 may be sequentially formed over the third mask pattern 133. The lower mask layer 171 may be formed to fill the plurality of first type second openings 161A1 to 161A6 and the plurality of second type second openings 161B1′ to 161B6′. The lower mask layer 171 may include a material having etch selectivity to the first stacked body 100A, the second stacked body 100B, the first insulating layer 131, and the third mask pattern 133. According to an embodiment, the lower mask layer 171 may include a carbon containing layer. The lower mask layer 171 may be formed using a spin coating method that allows uniform application. The upper mask layer 173 may include a material serving as an anti-reflection layer. According to an embodiment, the upper mask layer 173 may include silicon oxynitride (SiON).

Subsequently, a fourth photoresist pattern 175 may be formed over the upper mask layer 173. The fourth photoresist pattern 175 may include a plurality of openings 175OP. The plurality of openings 175OP may correspond to the plurality of first type second openings 161A1 to 161A6 and the plurality of second type second openings 161B1′ to 161B6′, respectively. Each of the plurality of openings 175OP may be formed to be narrower than each of the plurality of first type second openings 161A1 to 161A6 and the plurality of second type second openings 161B1′ to 161B6′.

Referring to FIG. 5K, the lower mask layer 171 may be exposed by exposing open areas of the upper mask layer 173 illustrated in FIG. 5J through the plurality of openings 175OP of the fourth photoresist pattern 175 illustrated in FIG. 5J. The exposed areas of the lower mask layer 171 may correspond to areas of the lower mask layer 171 disposed in the plurality of first type second openings 161A1 to 161A6 and the plurality of second type second openings 161B1′ to 161B6′ illustrated in FIG. 5J.

Subsequently, by etching the exposed areas of the lower mask layer 171, a portion of each of the plurality of first type second openings 161A1 to 161A6 and the plurality of second type second openings 161B1′ to 161B6′ illustrated in FIG. 5J may be opened. Thereafter, the second stacked body 100B and the first stacked body 100A may be etched through the opened plurality of first type second openings and plurality of second type second openings. In this case, a portion of the second stacked body 100B between each of the plurality of first type second openings 161A1 to 161A6 illustrated in FIG. 5J and a corresponding sacrificial pillar 113B may be etched, and a portion of the first stacked body 100A overlapping the plurality of second type second openings 161B1′ to 161B6′ illustrated in FIG. 5J may be etched. Thus, a plurality of first preliminary holes 181A1 to 181A6 of a first group PH1 may be formed, and a plurality of second preliminary holes 181B1 to 181B6 of a second group PH2 may be formed. The fourth photoresist pattern 175 and the upper mask layer 173 illustrated in FIG. 5J may be removed while the plurality of first preliminary holes 181A1 to 181A6 and the plurality of second preliminary holes 181B1 to 181B6 are formed or be removed through a separate removal process.

Each of the plurality of first preliminary holes 181A1 to 181A6 may expose a corresponding sacrificial pillar 113B and be formed to be narrower than each of the plurality of first type second openings 161A1 to 161A6 illustrated in FIG. 5J. A portion of a top surface 103B_T of each of the plurality of second sacrificial layers 103B forming the bottom surface of the plurality of first type second openings 161A1 to 161A6 illustrated in FIG. 5J may be protected by the lower mask layer 171.

Each of the plurality of second preliminary holes 181B1 to 181B6 may extend to pass through the lower interlayer insulating layer 101 of the first stacked body 100A and may be formed to be narrower than each of the plurality of second type second openings 161B1′ to 161B6′ illustrated in FIG. 5J. A portion of a top surface 103A_T of each of the plurality of first sacrificial layers 103A forming the bottom surface of the plurality of second type second openings 161B1′ to 161B6′ illustrated in FIG. 5J may be protected by the lower mask layer 171.

Referring to FIG. 5L, the plurality of sacrificial pillars 113B illustrated in FIG. 5K may be selectively removed through a plurality of first preliminary holes 181A1 to 181A6. Thus, the first stacked body 100A may be exposed along the sidewall of the plurality of first openings 111B.

Referring to FIG. 5M, the lower mask layer 171 illustrated in FIG. 5K may be removed. Thus, a first contact hole group H1 and a second contact hole group H2 may be defined.

The first contact hole group H1 may extend to pass through the first sub-area AR2A′ of the first stacked body 100A and to pass through the second stacked body 100B and the first insulating layer 131. The first contact hole group H1 may include a plurality of first contact holes 181A1′ to 181A6′. Each of the plurality of first contact holes 181A1′ to 181A6′ may be defined by coupling a first opening, a first preliminary hole, and a first type of second opening corresponding thereto and arranged in a line. Each of the plurality of first contact holes 181A1′ to 181A6′ may include a first guide H1_G corresponding to the bottom surface of the first type of second opening.

The second contact hole group H2 may extend to pass through the second sub-area AR2B′ of the first stacked body 100A and to pass through the second stacked body 100B and the first insulating layer 131. The second contact hole group H2 may include a plurality of second contact holes 181B1′ to 181B6′. Each of the plurality of second contact holes 181B1′ to 181B6′ may be defined by coupling a second preliminary hole and a second type of second opening corresponding thereto and arranged in a line. Each of the plurality of second contact holes 181B1′ to 181B6′ may include a second guide H2_G corresponding to the bottom surface of the second type of second opening.

Referring to FIG. 5N, a sidewall insulating layer 191 may be formed along the inner wall of each contact hole included in each of the first contact hole group H1 and the second contact hole group H2.

Referring to FIG. 5O, a support pillar 195 may be formed in the contact hole of each of the first contact hole group H1 and the second contact hole group H2. The support pillar 195 may be enclosed by the lower interlayer insulating layer 101, the plurality of first sacrificial layers 103A, the plurality of first interlayer insulating layers 105A, the plurality of second sacrificial layers 103B, the plurality of second interlayer insulating layers 105B, and the upper interlayer insulating layer 107.

Referring to FIG. 5P, the plurality of first sacrificial layers 103A and the plurality of second sacrificial layers 103B illustrated in FIG. 5O may be replaced with a plurality of conductive layers 201. To this end, a protective layer 197 may be formed over the first insulating layer 131 to cover the support pillar 195. Subsequently, the slit SI (see FIG. 3A or 3B) may be formed to pass through the protective layer 197, the first insulating layer 131, and the first stacked body 100A and the second stacked body 100B illustrated in FIG. 5O, and the plurality of first sacrificial layers 103A and the plurality of second sacrificial layers 103B illustrated in FIG. 5O may be selectively removed through the slit. Here, the support pillar 195 may support the lower interlayer insulating layer 101, the plurality of first interlayer insulating layers 105A, the plurality of second interlayer insulating layers 105B, and the upper interlayer insulating layer 107 in the second area AR2′, and may maintain gaps between the lower interlayer insulating layer 101, the plurality of first interlayer insulating layers 105A, the plurality of second interlayer insulating layers 105B, and the upper interlayer insulating layer 107. Each conductive layer 201 may be disposed in the gap. After forming the second blocking insulating layer BI2 illustrated in FIG. 4B in the gap, the conductive layer 201 may be formed on the second blocking insulating layer BI2.

Referring to FIG. 5Q, the protective layer 197 illustrated in FIG. 5P may be removed to expose the support pillar 195 illustrated in FIG. 5P. Subsequently, by removing the support pillar 195 illustrated in FIG. 5P, the sidewall insulating layer 191 illustrated in FIG. 5P may be exposed.

Thereafter, a portion of the sidewall insulating layer 191 illustrated in FIG. 5P may be etched using an etch-back process so that the first guide H1_G of each of the plurality of first contact holes 181A1′ to 181A6′ and the second guide H2_G of each of the plurality of second contact holes 181B1′ to 181B6′ are opened. Thus, the sidewall insulating layer 191 illustrated in FIG. 5P may be divided into a first sidewall insulation pattern 191A and a second sidewall insulation pattern 191B in the contact hole of each of the first contact hole group H1 and the second contact hole group H2. Further, when each conductive layer 201 is formed on the second blocking insulating layer, a portion of the second blocking insulating layer may be etched using the etching process of the sidewall insulating layer.

According to the above-described processes, a corresponding conductive layer 201 may be exposed between a corresponding first sidewall insulation pattern 191A and second sidewall insulation pattern 191B through each of the first guide H1_G and the second guide H2_G.

Referring to FIG. 5R, a gate contact plug 211 may be formed in the contact hole of each of the first contact hole group H1 and the second contact hole group H2 illustrated in FIG. 5Q. The gate contact plug 211 may contact a corresponding conductive layer 201 between the first sidewall insulation pattern 191A and the second sidewall insulation pattern 191B.

Referring to FIG. 5S, after forming the second insulating layer 221 over the first insulating layer 131, a plurality of conductive patterns 231A and 231B may be formed to penetrate at least one of the first insulating layer 131 and the second insulating layer 221. The plurality of conductive patterns 231A and 231B may include a bit line coupling structure 231A and a gate contact coupling structure 231B.

The bit line coupling structure 231A may penetrate the first insulating layer 131 and the second insulating layer 221 to contact the channel pillar 120. The gate contact coupling structure 231B may penetrate the second insulating layer 221 to contact the gate contact plug 211.

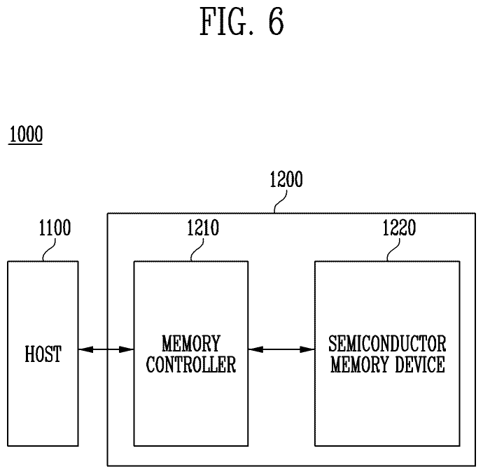

FIG. 6 is a block diagram illustrating an electronic system according to an embodiment of the present disclosure.

Referring to FIG. 6, an electronic system 1000 may be a computing system, a medical device, a communication device, a wearable device, a memory system, etc. The electronic system 1000 may include a host 1100 and a storage device 1200.

The host 1100 may store data in the storage device 1200 or may read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA (SATA) interface, a parallel-ATA (PATA) interface, a small computer system interface (SCSI), an enhanced small disk interface (ESDI), an integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. In an embodiment, the storage device 1200 may be a storage medium such as a solid state drive (SSD) or a universal serial bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. As described above with reference to FIGS. 4A to 4D, the semiconductor memory device 1220 may include a plurality of first conductive layers of a first sub-stacked body, a plurality of second conductive layers of a second sub-stacked body disposed over the first sub-stacked body, and a plurality of gate contact plugs penetrating the plurality of first conductive layers and the plurality of second conductive layers. Among the plurality of gate contact plugs, a first gate contact plug may include a first contact portion contacting a corresponding second conductive layer among the plurality of second conductive layers, a first portion penetrating the first sub-stacked body, and a second portion extending from the first portion toward the first contact portion.

An embodiment of present disclosure provides a semiconductor memory device, in which a contact portion of a gate contact plug is formed relatively wide, thereby securing a contact surface between the contact portion and a conductive layer of a stacked body, and improving operational reliability.

An embodiment of present disclosure provides a semiconductor memory device, in which an opening and a preliminary hole for a contact hole are formed through individual processes, so that the difficulty of a manufacturing process for providing the contact hole can be lowered even if the aspect ratio of the contact hole is increased, and operational reliability is improved.

According to an embodiment of the present disclosure, a preliminary hole narrower than an opening is coupled to the opening, so that a bottom surface of the opening can be stably opened, and the electrical connection structure of the gate contact plug can be stably provided.

What is claimed is:

1. A semiconductor memory device, comprising:
a gate stacked body including a cell array area and a contact area extending from the cell array area in a first direction, and including a plurality of conductive layers and a plurality of interlayer insulating layers that are alternately stacked in a second direction intersecting a plane extending in the first direction; and
a plurality of gate contact plugs penetrating the plurality of conductive layers and the plurality of interlayer insulating layers in the contact area,
wherein the plurality of conductive layers comprise a plurality of first conductive layers arranged in the second direction to form a first sub-stacked body and a plurality of second conductive layers arranged over the first sub-stacked body in the second direction to form a second sub-stacked body,
wherein the plurality of gate contact plugs comprise a first gate contact plug contacting a corresponding second conductive layer among the plurality of second conductive layers,
wherein the first gate contact plug comprises a first portion penetrating the first sub-stacked body, a first contact portion spaced apart from the first portion in the second direction and contacting the corresponding second conductive layer, and a second portion extending from the first portion toward the first contact portion to contact the first contact portion, and
wherein the second portion in the first direction is narrower than the first contact portion.

2. The semiconductor memory device according to claim 1, wherein the second portion in the first direction is narrower than the first portion.

3. The semiconductor memory device according to claim 1, wherein:
the first contact portion of the first gate contact plug comprises a first protrusion protruding toward the second conductive layer in a negative first direction to form a first contact surface with the second conductive layer, and
the first contact portion of the first gate contact plug comprises a second protrusion protruding toward the second conductive layer in a positive first direction to form another first contact surface with the second conductive layer.

4. The semiconductor memory device according to claim 1, further comprising:
a sidewall insulating structure extending along a sidewall of the first gate contact plug,
wherein the sidewall insulating structure comprises a first sidewall insulation pattern and a second sidewall insulation pattern that are spaced apart from each other by a contact surface between the first contact portion of the first gate contact plug and the corresponding second conductive layer.

5. The semiconductor memory device according to claim 4, wherein:
the first sidewall insulation pattern encloses an upper sidewall of the first contact portion protruding beyond the contact surface in the second direction, and
the second sidewall insulation pattern encloses a sidewall of the first portion, and extends onto a sidewall of the second portion.

6. The semiconductor memory device according to claim 1, wherein:
the contact area comprises a first contact area and a second contact area that are adjacent to each other,
the plurality of gate contact plugs comprise the first gate contact plug disposed in the first contact area and a second gate contact plug disposed in the second contact area, and
the second gate contact plug contacts a corresponding first conductive layer among the plurality of first conductive layers.

7. The semiconductor memory device according to claim 6, wherein:
the second gate contact plug comprises a second contact portion extending from the corresponding first conductive layer in the second direction to penetrate the second sub-stacked body, and an extension portion extending from the second contact portion in a third direction opposite to the second direction, and
the extension portion in the first direction is narrower than the second contact portion.

8. The semiconductor memory device according to claim 7, wherein:
the second contact portion of the second gate contact plug comprises a first protrusion protruding toward the first conductive layer in a negative first direction to form a second contact surface with the first conductive layer, and
the second contact portion of the second gate contact plug comprises a second protrusion protruding toward the first conductive layer in a positive first direction to form another second contact surface with the first conductive layer.

9. The semiconductor memory device according to claim 7, further comprising:
a sidewall insulating structure extending along a sidewall of the second gate contact plug,
wherein the sidewall insulating structure comprises a first sidewall insulation pattern and a second sidewall insulation pattern that are spaced apart from each other by a contact surface between the second contact portion of the second gate contact plug and the corresponding first conductive layer.

10. The semiconductor memory device according to claim 9, wherein:
the first sidewall insulation pattern encloses an upper sidewall of the second contact portion extending from the contact surface in the second direction, and
the second sidewall insulation pattern encloses a sidewall of the extension portion.

11. The semiconductor memory device according to claim 1, further comprising:
a channel layer penetrating the plurality of conductive layers and the plurality of interlayer insulating layers in the cell array area; and
a memory layer provided between the channel layer and the gate stacked body.

12. A semiconductor memory device, comprising:
a gate stacked body including a cell array area and a contact area extending from the cell array area in a first direction, and including a plurality of conductive layers and a plurality of interlayer insulating layers that are alternately stacked in a second direction intersecting a plane extending in the first direction; and
a first sub-contact set comprising a plurality of first gate contact plugs penetrating the plurality of conductive layers and the plurality of interlayer insulating layers in the contact area,
wherein the plurality of conductive layers comprise a plurality of first conductive layers arranged in the second direction to form a first sub-stacked body and a plurality of second conductive layers arranged over the first sub-stacked body in the second direction to form a second sub-stacked body and contact the plurality of first gate contact plugs, respectively,
wherein the first sub-contact set comprises a plurality of first portions penetrating the first sub-stacked body and forming lower portions of the plurality of first gate contact plugs, a plurality of first contact portions forming upper portions of the plurality of first gate contact plugs, and a plurality of second portions forming middle portions of the plurality of first gate contact plugs, and
wherein a sidewall of each of the plurality of first gate contact plugs comprises a groove defined between a corresponding first contact portion among the plurality of first contact portions and a corresponding first portion among the plurality of first portions.

13. The semiconductor memory device according to claim 12, wherein the plurality of first contact portions contact the plurality of second conductive layers, respectively.

14. The semiconductor memory device according to claim 12, wherein the plurality of first portions are formed to have the substantially same length along the second direction.

15. The semiconductor memory device according to claim 12, wherein the plurality of second portions are formed to have different lengths along the second direction.

16. The semiconductor memory device according to claim 12, further comprising:
a first sidewall insulation pattern enclosing a sidewall of each of the plurality of first contact portions; and
a second sidewall insulation pattern enclosing a sidewall of each of the plurality of first portions, and extending onto a sidewall of each of the plurality of second portions.

17. The semiconductor memory device according to claim 16, wherein:
each of the plurality of first contact portions comprises a contact surface contacting a corresponding second conductive layer among the plurality of second conductive layers, and
the first sidewall insulation pattern and the second sidewall insulation pattern are spaced apart from each other by the contact surface.

18. The semiconductor memory device according to claim 12, further comprising:
a second sub-contact set including a plurality of second gate contact plugs that penetrate the plurality of conductive layers and the plurality of interlayer insulating layers in the contact area,
wherein the second sub-contact set comprises a plurality of second contact portions forming upper portions of the plurality of second gate contact plugs and a plurality of extension portions forming lower portions of the plurality of second gate contact plugs, and
wherein each of the plurality of second contact portions comprises a contact surface contacting a corresponding first conductive layer among the plurality of first conductive layers, and extends from the contact surface in the second direction to penetrate the second sub-stacked body.

19. The semiconductor memory device according to claim 18, wherein:
each of the plurality of extension portions extends from a corresponding second contact portion among the plurality of second contact portions in a third direction opposite to the second direction, and
each of the plurality of extension portions in the first direction is narrower than each of the plurality of second contact portions.

20. The semiconductor memory device according to claim 18, further comprising:
a first sidewall insulation pattern enclosing a sidewall of each of the plurality of second contact portions; and
a second sidewall insulation pattern enclosing a sidewall of each of the plurality of extension portions,
wherein the first sidewall insulation pattern and the second sidewall insulation pattern are spaced apart from each other by the contact surface.

21. The semiconductor memory device according to claim 18, wherein a length of the plurality of second portions in the second direction is proportional to a separation distance from the second sub-contact set.
